(19) United States
(12) Patent Application Publication
(10) Pub. No.: US 2024/0369941 A1
(43) Pub. Date: Nov. 7, 2024

(54) TECHNIQUES FOR ADDING AND REMOVING STRUCTURAL FEATURES DURING GRADIENT-BASED OPTIMIZATION

(71) Applicant: X Development LLC, Mountain View, CA (US)

(72) Inventors: Aaditya Chandrasekhar, Madison, WI (US); Rhett Stucki, Fresno, CA (US); Ian Williamson, Palo Alto, CA (US)

(21) Appl. No.: 18/311,837

(22) Filed: May 3, 2023

(51) Int. Cl. G03F 7/20; G03F 7/00; G05B 19/4097

(52) U.S. Cl. CPC G03F 7/705; G03F 7/0005; G05B 19/4097; G05B 2219/45028

(57) ABSTRACT

In some embodiments, a computer-implemented method for designing a physical device is provided. A computing system determines whether a feature from a list of features is present in a set of structural parameters by, in response to determining whether a feature presence function indicates that the feature should be included in the set of structural parameters or not, updating the set of structural parameters to include the feature or refraining from updating the set of structural parameters to include the feature, accordingly. The computing system simulates performance of the initial design using the set of structural parameters to determine a performance loss value, determines a structural gradient based on the performance loss value, determines a feature gradient based on the performance loss value, and updates the features in the list of features based on the structural gradient and the feature gradient.

### TECHNICAL FIELD

This disclosure relates generally to inverse design of physical devices, and in particular but not exclusively, relates to inverse design of photonic devices.

### BACKGROUND

Fiber-optic communication is typically employed to transmit information from one place to another via light that has been modulated to carry the information. For example, many telecommunication companies use optical fiber to transmit telephone signals, internet communication, and cable television signals. But the cost of deploying optical fibers for fiber-optic communication may be prohibitive. As such, techniques have been developed to more efficiently use the bandwidth available within a single optical fiber. Wavelength-division multiplexing is one such technique that bundles multiple optical carrier signals onto a single optical fiber using different wavelengths.

### BRIEF SUMMARY

In some embodiments, a non-transitory computer-readable medium having logic stored thereon is provided. The logic, in response to execution by one or more processors of a computing system, causes the computing system to perform actions for designing a physical device. The actions include the computing system generating an initial design based on a design specification, wherein the initial design includes a list of features. The actions also include, for each feature of the list of features, determining whether the feature is present in a set of structural parameters by: in response to determining a feature presence function indicates that the feature should be included in the set of structural parameters, updating the set of structural parameters to include the feature; and in response to determining the feature presence function indicates that the feature should not be included in the set of structural parameters, refraining from updating the set of structural parameters to include the feature. The actions also include simulating, by the computing system, performance of the initial design using the set of structural parameters to determine a performance loss value; determining, by the computing system, a structural gradient based on the performance loss value; determining, by the computing system, a feature gradient based on the performance loss value; and updating, by the computing system, the features in the list of features based on the structural gradient and the feature gradient.

In some embodiments, a computer-implemented method for designing a physical device is provided. A computing system generates an initial design based on a design specification. The initial design includes a list of features. For each feature of the list of features, the computing system determines whether the feature is present in a set of structural parameters by, in response to determining a feature presence function indicates that the feature should be included in the set of structural parameters, updating the set of structural parameters to include the feature; and in response to determining the feature presence function indicates that the feature should not be included in the set of structural parameters, refraining from updating the set of structural parameters to include the feature. The computing system simulates performance of the initial design using the set of structural parameters to determine a performance loss value. The computing system determines a structural gradient based on the performance loss value. The computing system determines a feature gradient based on the performance loss value. The computing system updates the features in the list of features based on the structural gradient and the feature gradient.

### BRIEF DESCRIPTION OF THE SEVERAL VIEWS OF THE DRAWINGS

Non-limiting and non-exhaustive embodiments of the invention are described with reference to the following figures, wherein like reference numerals refer to like parts throughout the various views unless otherwise specified. Not all instances of an element are necessarily labeled so as not to clutter the drawings where appropriate. The drawings are not necessarily to scale, emphasis instead being placed upon illustrating the principles being described. To easily identify the discussion of any particular element or act, the most significant digit or digits in a reference number refer to the figure number in which that element is first introduced.

FIG. 1 is a functional block diagram illustrating a non-limiting example embodiment of a system for optical communication between two optical communication devices via an optical signal, according to various aspects of the present disclosure.

FIG. 2A and FIG. 2B respectively illustrate a non-limiting example embodiment of a demultiplexer and multiplexer, according to various aspects of the present disclosure.

FIG. 2C illustrates a a non-limiting example embodiment of a distinct wavelength channel of a multi-channel optical signal, according to various aspects of the present disclosure.

FIG. 3A-FIG. 3D illustrate different views of a non-limiting example embodiment of a photonic demultiplexer, according to various aspects of the present disclosure.

FIG. 4A and FIG. 4B illustrate a more detailed cross-sectional view of a dispersive region of a non-limiting example embodiment of a photonic demultiplexer, according to various aspects of the present disclosure.

FIG. 5 is a functional block diagram illustrating a non-limiting example embodiment of a system for generating a design of a photonic integrated circuit, according to various aspects of the present disclosure.

FIG. 6A illustrates a non-limiting example embodiment of a simulated environment describing a photonic integrated circuit, according to various aspects of the present disclosure.

FIG. 6B illustrates a non-limiting example embodiment of an operational simulation of a photonic integrated circuit, according to various aspects of the present disclosure.

FIG. 6C illustrates a non-limiting example embodiment of an adjoint simulation within the simulated environment by backpropagating a loss value, according to various aspects of the present disclosure.

FIG. 7 is a schematic illustration of a non-limiting example embodiment of a parameterization of an initial design that uses geometric shape primitives, according to various aspects of the present disclosure.

FIG. 8A is a flow chart illustrating example time steps for an operational simulation and an adjoint simulation, in accordance with various aspects of the present disclosure.

FIG. 8B is a chart illustrating the relationship between the update operation for the operational simulation and the adjoint simulation (e.g., backpropagation), in accordance with an embodiment of the present disclosure.

FIG. 9A-FIG. 9B are a flowchart that illustrates a non-limiting example embodiment of a method 900 for generating a design of physical device such as a photonic integrated circuit that allows an optimizer to adjust a number of included features, in accordance with various aspects of the present disclosure.

FIG. 10 includes schematic illustrations of a first signed distance field and a second signed distance field according to various aspects of the present disclosure.

FIG. 11A is a chart that illustrates a non-limiting example embodiment of a feature presence function according to various aspects of the present disclosure.

FIG. 11B illustrates a non-limiting example embodiment of a feature gradient function according to various aspects of the present disclosure.

FIG. 12A-FIG. 12D illustrate changes to a design that may be introduced by iterations of the optimization loop illustrated and described herein.

### DETAILED DESCRIPTION

Embodiments of techniques for inverse design of physical devices are described herein, in the context of generating designs for photonic integrated circuits (including a multi-channel photonic demultiplexer or multiplexer). In the following description numerous specific details are set forth to provide a thorough understanding of the embodiments. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

Wavelength division multiplexing and its variants (e.g., dense wavelength division multiplexing, coarse wavelength division multiplexing, and the like) take advantage of the bandwidth of optical fibers by bundling multiple optical carrier signals onto a single optical fiber. Once the multiple carrier signals are bundled together, they are transmitted from one place to another over the single optical fiber where they may be demultiplexed to be read out by an optical communication device. However, devices that decouple the carrier signals from one another remain prohibitive in terms of cost, size, and the like.

Moreover, design of photonic devices, such as those used for optical communication, are traditionally designed via conventional techniques sometimes determined through a simple guess and check method or manually-guided grid-search in which a small number of design parameters from pre-determined designs or building blocks are adjusted for suitability to a particular application. However, in actuality, these devices may have design parameters ranging from hundreds all the way to many billions or more, dependent on the device size and functionality. Thus, as functionality of photonic devices increases and manufacturing tolerances improve to allow for smaller device feature sizes, it becomes increasingly important to take full advantage of these improvements via optimized device design.

Described herein are embodiments of a photonic integrated circuit (e.g., a multi-channel photonic demultiplexer and/or multiplexer) having a design obtainable by an inverse design process, and techniques for the design thereof. More specifically, techniques described in embodiments herein utilize gradient-based optimization in combination with first-principle simulations to generate a design from an understanding of the underlying physics that are expected to govern the operation of the photonic integrated circuit. It is appreciated in other embodiments, design optimization of photonic integrated circuits without gradient-based techniques may also be used. Advantageously, embodiments and techniques described herein are not limited to conventional techniques used for design of photonic devices, in which a small number of design parameters for pre-determined building blocks are adjusted based on suitability to a particular application. Rather, the first-principles based designs described herein are not necessarily dependent on human intuition and generally may result in designs which outstrip current state-of-the-art designs in performance, size, robustness, or a combination thereof. Further still, rather than being limited to a small number of design parameters due to conventional techniques, the embodiments and techniques described herein may provide scalable optimization of a nearly unlimited number of design parameters. It will also be appreciated that, though the design and fabrication of photonic integrated circuits is described throughout the present text, similar inverse design techniques may be used to generate designs for other types of physical devices.

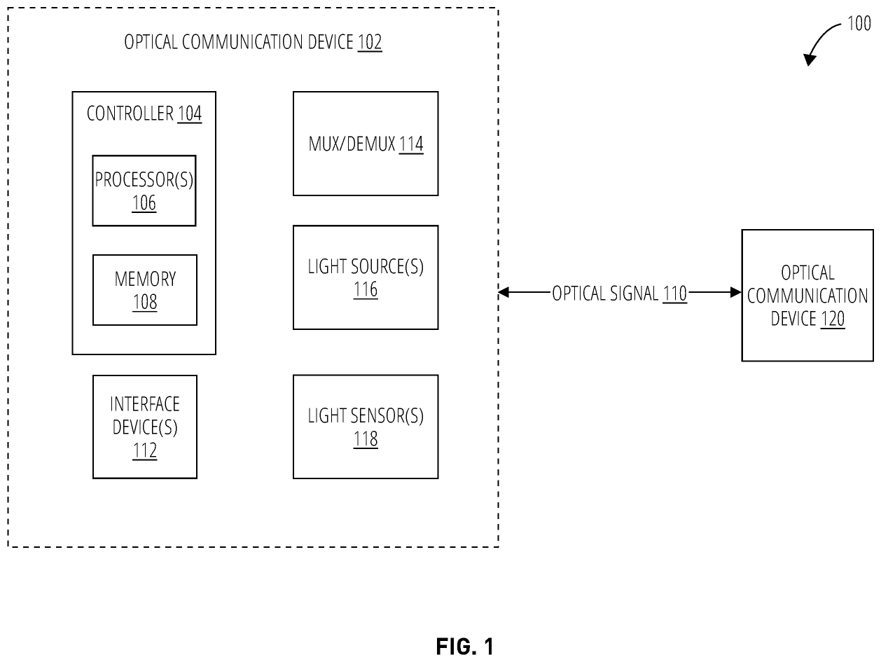

FIG. 1 is a functional block diagram illustrating a system 100 for optical communication (e.g., via wavelength division multiplexing or other techniques) between optical communication device 102 and optical communication device 120 via optical signal 110, in accordance with various aspects of the present disclosure. More generally, optical communication device 102 is configured to transmit information by modulating light from one or more light sources into a multi-channel optical signal 110 (e.g., a singular optical signal that includes a plurality of distinct wavelength channels) that is subsequently transmitted from optical communication device 102 to optical communication device 120 via an optical fiber, a light guide, a wave guide, or other photonic device. Optical communication device 120 receives the multi-channel optical signal 110 and demultiplexes each of the plurality of distinct wavelength channels from the multi-channel optical signal 110 to extract the transmitted information. It is appreciated that in some embodiments optical communication device 102 and optical communication device 120 may be distinct and separate devices (e.g., an optical transceiver or transmitter communicatively coupled via one or more optical fibers to a separate optical transceiver or receiver). However, in other embodiments, optical communication device 102 and optical communication device 120 may be part of a singular component or device (e.g., a smartphone, a tablet, a computer, optical device, or the like). For example, optical communication device 102 and optical communication device 120 may both be constituent components on a monolithic integrated circuit that are coupled to one another via a waveguide that is embedded within the monolithic integrated circuit and is adapted to carry optical signal 110 between optical communication device 102 and optical communication device 120 or otherwise transmit the optical signal between one place and another.

In the illustrated embodiment, optical communication device 102 includes a controller 104, one or more interface device(s) 112 (e.g., fiber optic couplers, light guides, waveguides, and the like), a multiplexer (mux), demultiplexer (demux), or combination thereof (MUX/DEMUX 114), one or more light source(s) 116 (e.g., light emitting diodes, lasers, and the like), and one or more light sensor(s) 118 (e.g., photodiodes, phototransistors, photoresistors, and the like) coupled to one another. The controller includes one or more processor(s) 106 (e.g., one or more central processing units, application specific circuits, field programmable gate arrays, or otherwise) and memory 108 (e.g., volatile memory such as DRAM and SAM, non-volatile memory such as ROM, flash memory, and the like). It is appreciated that optical communication device 120 may include the same or similar elements as optical communication device 102, which have been omitted for clarity.

Controller 104 orchestrates operation of optical communication device 102 for transmitting and/or receiving optical signal 110 (e.g., a multi-channel optical signal having a plurality of distinct wavelength channels or otherwise). Controller 104 includes software (e.g., instructions included in memory 108 coupled to processor 106) and/or hardware logic (e.g., application specific integrated circuits, field-programmable gate arrays, and the like) that when executed by controller 104 causes controller 104 and/or optical communication device 102 to perform operations.

In one embodiment, controller 104 may choreograph operations of optical communication device 102 to cause light source(s) 116 to generate a plurality of distinct wavelength channels that are multiplexed via MUX/DEMUX 114 into a multi-channel optical signal 110 that is subsequently transmitted to optical communication device 120 via interface device 112. In other words, light source(s) 116 may output light having different wavelengths (e.g., 1271 nm, 1291 nm, 1311 nm, 1331 nm, 1506 nm, 1514 nm, 1551 nm, 1571, or otherwise) that may be modulated or pulsed via controller 104 to generate a plurality of distinct wavelength channels representative of information. The plurality of distinct wavelength channels are subsequently combined or otherwise multiplexed via MUX/DEMUX 114 into a multi-channel optical signal 110 that is transmitted to optical communication device 120 via interface device 112. In the same or another embodiment, controller 104 may choreograph operations of optical communication device 102 to cause a plurality of distinct wavelength channels to be demultiplexed via MUX/DEMUX 114 from a multi-channel optical signal 110 that is received via interface device 112 from optical communication device 120.

It is appreciated that in some embodiments certain elements of optical communication device 102 and/or optical communication device 120 may have been omitted to avoid obscuring certain aspects of the disclosure. For example, optical communication device 102 and optical communication device 120 may include amplification circuitry, lenses, or components to facilitate transmitting and receiving optical signal 110. It is further appreciated that in some embodiments optical communication device 102 and/or optical communication device 120 may not necessarily include all elements illustrated in FIG. 1. For example, in one embodiment optical communication device 102 and/or optical communication device 120 are passive devices that operate as an intermediary device that may passively multiplex a plurality of distinct wavelength channels into a multi-channel optical signal 110 and/or demultiplex a plurality of distinct wavelength channels from a multi-channel optical signal 110.

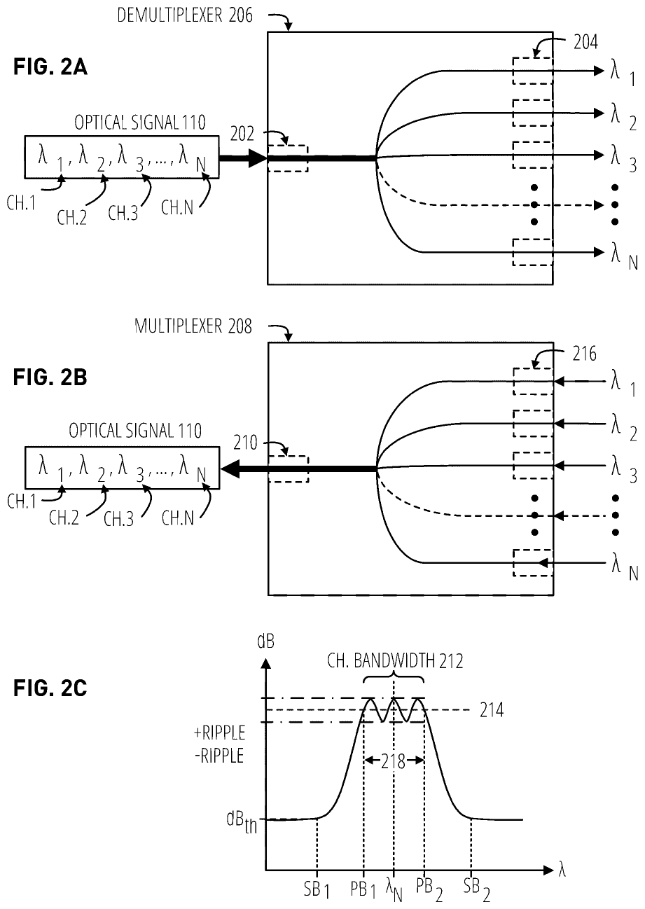

FIG. 2A and FIG. 2B respectively illustrate an example demultiplexer 206 and multiplexer 208, in accordance with various aspects of the present disclosure. Demultiplexer 206 and multiplexer 208 are possible embodiments of MUX/DEMUX 114 illustrated in FIG. 1, and which may be part of an integrated photonic circuit, silicon photonic device, or otherwise

As illustrated in FIG. 2A, demultiplexer 206 includes an input region 202 and a plurality of output regions 204. Demultiplexer 206 is configured to receive a multi-channel optical signal 110 that includes a plurality of distinct wavelength channels (e.g., Ch. 1, Ch. 2, Ch. 3, . . . . Ch. N, each having a center wavelength respectively corresponding to λ1, 22, 23, . . . . AN) via input region 202 (e.g., a waveguide that may correspond to interface device 112 illustrated in FIG. 1) to optically separate each of the plurality of distinct wavelength channels from the multi-channel optical signal 110 and respectively guide each of the plurality of distinct wavelength channels to a corresponding one of a plurality of output regions 204 (e.g., a plurality of waveguides that may correspond to interface device(s) 112 illustrated in FIG. 1). More specifically, in the illustrated embodiment, each of the output regions 204 receives a portion of the multi-channel optical signal that corresponds to, or is otherwise representative of, one of the plurality of distinct wavelength channels that may be output as plurality of optical signals (e.g., λ₁, λ₂, λ₃, . . . λ_{N}). The plurality of output regions 204 may each be coupled to a respective light sensor (e.g., corresponding to light sensor(s) 118 illustrated in FIG. 1), which may be utilized to convert the optical signals demultiplexed from the multi-channel optical signal 110 into electrical signals for further processing.

In the illustrated embodiment of FIG. 2B, multiplexer 208 includes a plurality of input regions 216 and an output region 210. Multiplexer 208 is configured to receive a plurality of distinct optical signals (e.g., λ₁, λ₂, λ₃, . . . λ_{N}), each at a respective one of the plurality of input regions 216 (e.g., a plurality of waveguides that may correspond to interface device(s) 112 illustrated in FIG. 1). Multiplexer 208 is structured or otherwise configured to optically combine (i.e., multiplex) each of the plurality of distinct wavelength channels into a multi-channel optical signal 110 that is guided to output region 210 (e.g., a waveguide that may correspond to interface device 112 illustrated in FIG. 1). It is appreciated that in some embodiments, demultiplexer 206 illustrated in FIG. 2A and multiplexer 208 illustrated in FIG. 2B may be bidirectional such that each device may function as both a demultiplexer and multiplexer.

FIG. 2C illustrates an example distinct wavelength channel of a multi-channel optical signal (e.g., Ch. N is multi-channel optical signal 110 illustrated in FIG. 1, FIG. 2A, and FIG. 2B), in accordance with various aspects of the present disclosure. The example channel may be representative of an individual channel included in a plurality of distinct wavelength channels of the multi-channel optical signal that may be demultiplexed and/or multiplexed by demultiplexer 206 of FIG. 2A and/or multiplexer 208 of FIG. 2B. Each of the distinct wavelength channels may have different center wavelengths (AN) including at least one of 1271 nm, 1291 nm, 1311 nm, 1331 nm, 1506 nm, 1514 nm, 1551 nm, or 1571 nm, or otherwise. In the illustrated embodiment of FIG. 2C, the distinct wavelength channel has a channel bandwidth 212 of approximately 13 nm wide. However, in other embodiments the channel bandwidth may be different than 13 nm wide. Rather, the channel bandwidth may be considered a configurable parameter that is dependent upon the structure of MUX/DEMUX 114 of FIG. 1, demultiplexer 206 of FIG. 2A, and/or multiplexer 208 of FIG. 2B. For example, in some embodiments each of the plurality of distinct wavelength channels may share a common bandwidth that may correspond to 13 nm or otherwise. Referring back to FIG. 2C, the channel bandwidth 212 may be defined as the width of a passband region 218 (i.e., the region defined as being between PB₁ and PB₂). The passband region 218 may represent an approximate power transmission of a demultiplexer or multiplexer. It is appreciated that in some embodiments the passband region 218 may include ripple as illustrated in FIG. 2C, which corresponds to fluctuations within the passband region 218. In one or more embodiments, the ripple within the passband region around a central value 214 may be +/−2 dB or less, +/−1 dB or less, +/−0.5 dB or less, or otherwise. In some embodiments, the channel bandwidth 212 may be defined by the passband region 218. In other embodiments, the channel bandwidth 212 may be defined as the measured power above a threshold (e.g., dBₜₕ). For example, demultiplexer 206 illustrated in FIG. 2A may optically separate channel N from multi-channel optical signal 110 and have a corresponding channel bandwidth for channel N equivalent to the range of wavelengths above a threshold value that are transmitted to the output region 204 mapped to channel N (i.e., λ_{N}). In the same or other embodiments, isolation of the channel (i.e., defined by channel bandwidth 212) may also be considered when optimizing the design. The isolation may be defined as a ratio between the passband region 218 and the stopband regions (e.g., regions less than SB₁ and greater than SB₂). It is further appreciated that transition band regions (e.g., a first transition region between SB₁ and PB₁ and a second transition region between PB₂ and SB₂) are exemplary and may be exaggerated for the purposes of illustration. In some embodiments, optimization of the design of the photonic demultiplexer may also include a target metric for a slope, width, or the like of the transition band regions.

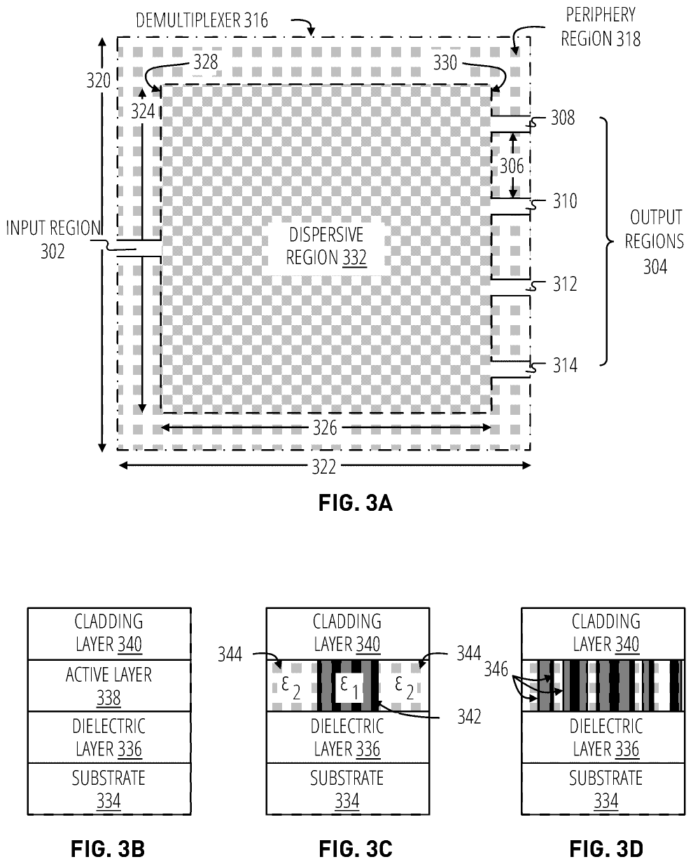

FIG. 3A-FIG. 3D illustrate different views of an example photonic demultiplexer, in accordance with an embodiment of the present disclosure. Photonic demultiplexer 316 is one possible implementation of MUX/DEMUX 114 illustrated in FIG. 1 and demultiplexer 206 illustrated in FIG. 2A. It is further appreciated that while discussion henceforth may be directed towards photonic integrated circuits capable of demultiplexing a plurality of distinct wavelength channels from a multi-channel optical signal, that in other embodiments, a demultiplexer (e.g., demultiplexer 316) may also or alternatively be capable of multiplexing a plurality of distinct wavelength channels into a multi-channel optical signal, in accordance with embodiments of the present disclosure.

FIG. 3A illustrates a cross-sectional view of demultiplexer 316 along a lateral plane within an active layer defined by a width 320 and a length 322 of the demultiplexer 316. As illustrated, demultiplexer 316 includes an input region 302 (e.g., comparable to input region 202 illustrated in FIG. 2A), a plurality of output regions 304 (e.g., comparable to plurality of output regions 204 illustrated in FIG. 2A), and a dispersive region optically disposed between the input region 302 and plurality of output regions 304. The input region 302 and plurality of output regions 304 (e.g., output region 308, output region 310, output region 312, and output region 314) may each be waveguides (e.g., slab waveguide, strip waveguide, slot waveguide, or the like) capable of propagating light along the path of the waveguide. The dispersive region 332 includes a first material and a second material (see, e.g., FIG. 3D) inhomogeneously interspersed to form a plurality of interfaces that each correspond to a change in refractive index of the dispersive region 332 and collectively structure the dispersive region 332 to optically separate each of a plurality of distinct wavelength channels (e.g., Ch. 1, Ch. 2, Ch. 3, . . . Ch. N illustrated in FIG. 2A) from a multi-channel optical signal (e.g., optical signal 110 illustrated in FIG. 2A) and respectively guide each of the plurality of distinct wavelength channels to a corresponding one of the plurality of output regions 304 when the input region 302 receives the multi-channel optical signal. In other words, input region 302 is adapted to receive the multi-channel optical signal including a plurality of distinct wavelength channels and the plurality of output regions 304 are adapted to each receive a corresponding one of the plurality of distinct wavelength channels demultiplexed from the multi-channel optical signal via dispersive region 332.

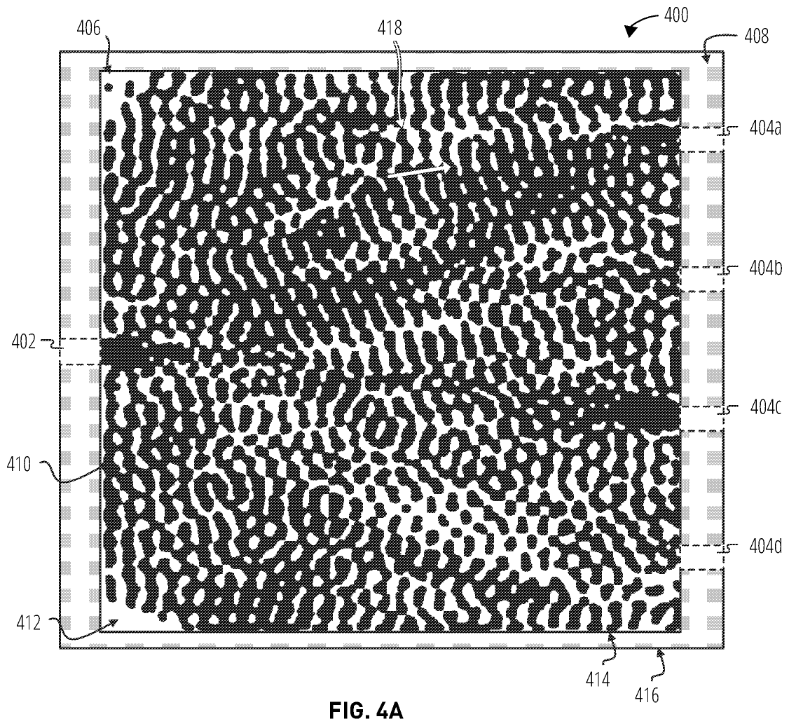

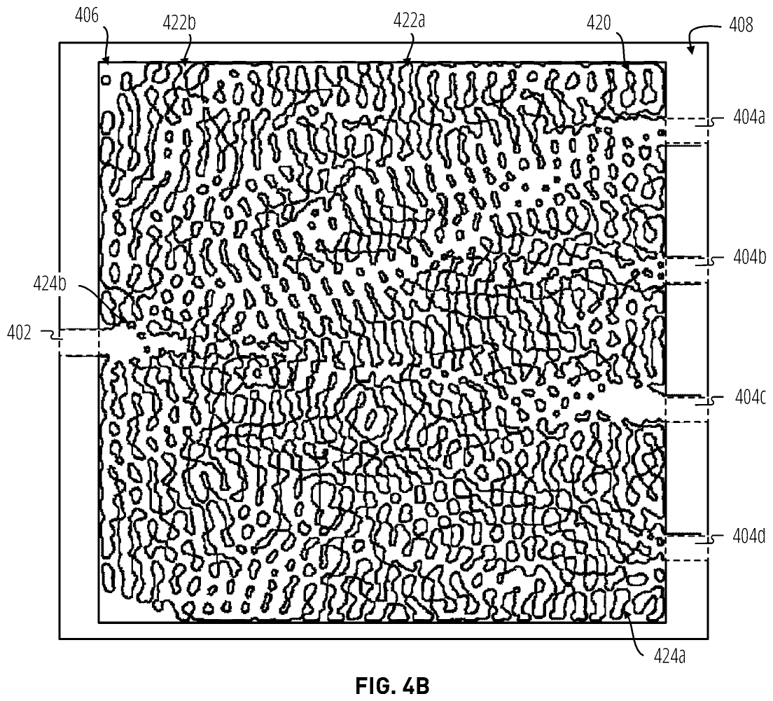

As illustrated in FIG. 3A, and more clearly shown in FIG. 3D and FIG. 4A-FIG. 4B, the shape and arrangement of the first and second material that are inhomogeneously interspersed create a plurality of interfaces that collectively form a material interface pattern along a cross-sectional area of dispersive region 332 that is at least partially surrounded by a periphery region 318 that includes the second material. In some embodiments periphery region 318 has a substantially homogeneous composition that includes the second material. In the illustrated embodiment, dispersive region 332 includes a first side 328 and a second side 330 that each interface with an inner boundary (i.e., the unlabeled dashed line of periphery region 318 disposed between dispersive region 332 and dashed-dotted line corresponding to an outer boundary of periphery region 318). First side 328 and second side 330 are disposed correspond to opposing sides of dispersive region 332. Input region 302 is disposed proximate to first side 328 (e.g., one side of input region 302 abuts first side 328 of dispersive region 332) while each of the plurality of output regions 304 are disposed proximate to second side 330 (e.g., one side of each of the plurality of output regions 304 abuts second side 330 of dispersive region 332).

In the illustrated embodiment each of the plurality of output regions 304 are parallel to each other one of the plurality of output regions 304. However, in other embodiments the plurality of output regions 304 may not be parallel to one another or even disposed on the same side (e.g., one or more of the plurality of output regions 304 and/or input region 302 may be disposed proximate to sides of dispersive region 332 that are adjacent to first side 328 and/or second side 330). In some embodiments adjacent ones of the plurality of output regions are separated from each other by a common separation distance when the plurality of output regions includes at least three output regions. For example, as illustrated adjacent output region 308 and output region 310 are separated from one another by distance 306, which may be common to the separation distance between other pairs of adjacent output regions.

As illustrated in the embodiment of FIG. 3A, demultiplexer 316 includes four output regions 304 (e.g., output region 308, output region 310, output region 312, output region 314) that are each respectively mapped (i.e., by virtue of the structure of dispersive region 332) to a respective one of four channels included in a plurality of distinct wavelength channels. More specifically, the plurality of interfaces of dispersive region 332, defined by the inhomogeneous interspersion of a first material and a second material, form a material interface pattern along a cross-sectional area of the dispersive region 332 (e.g., as illustrated in FIG. 3A, FIG. 4A, or FIG. 4B) to cause the dispersive region 332 to optically separate each of the four channels from the multi-channel optical signal and route each of the four channels to a respective one of the four output regions 304 when the input region 302 regions the multi-channel optical signal.

It is noted that the first material and second material of dispersive region 332 are arranged and shaped within the dispersive region such that the material interface pattern is substantially proportional to a design obtainable with an inverse design process, which will be discussed in greater detail later in the present disclosure. More specifically, in some embodiments, the inverse design process may include iterative gradient-based optimization of a design based at least in part on a loss function that incorporates a performance loss (e.g., to enforce functionality) and a fabrication loss (e.g., to enforce fabricability and binarization of a first material and a second material) that is reduced or otherwise adjusted via iterative gradient-based optimization to generate the design. In the same or other embodiment, other optimization techniques may be used instead of, or jointly with, gradient-based optimization. Advantageously, this allows for optimization of a near unlimited number of design parameters to achieve functionality and performance within a predetermined area that may not have been possible with conventional design techniques.

For example, in one embodiment dispersive region 332 is structured to optically separate each of the four channels from the multi-channel optical signal within a predetermined area of 35 μm×35 μm (e.g., as defined by width 324 and length 326 of dispersive region 332) when the input region 302 receives the multi-channel optical signal. In the same or another embodiment, the dispersive region is structured to accommodate a common bandwidth for each of the four channels, each of the four channels having different center wavelengths. In one embodiment the common bandwidth is approximately 13 nm wide and the different center wavelengths is selected from a group consisting of 1271 nm, 1291 nm, 1311 nm, 1331 nm, 1506 nm, 1514 nm, 1551 nm, and 1571 nm. In some embodiments, the entire structure of demultiplexer 316 (e.g., including input region 302, periphery region 318, dispersive region 332, and plurality of output regions 304) fits within a predetermined area (e.g., as defined by width 320 and length 322). In one embodiment the predetermined area is 35 μm×35 μm. It is appreciated that in other embodiments dispersive region 332 and/or demultiplexer 316 fits within other areas greater than or less than 35 μm×35 μm, which may result in changes to the structure of dispersive region 332 (e.g., the arrangement and shape of the first and second material) and/or other components of demultiplexer 316.

In the same or other embodiments the dispersive region is structured to have a power transmission of −2 dB or greater from the input region 302, through the dispersive region 332, and to the corresponding one of the plurality of output regions 304 for a given wavelength within one of the plurality of distinct wavelength channels. For example, if channel 1 of a multi-channel optical signal is mapped to output region 308, then when demultiplexer 316 receives the multi-channel optical signal at input region 302 the dispersive region 332 will optically separate channel 1 from the multi-channel optical signal and guide a portion of the multi-channel optical signal corresponding to channel 1 to output region 308 with a power transmission of −2 dB or greater. In the same or another embodiment, dispersive region 332 is structured such that an adverse power transmission (i.e., isolation) for the given wavelength from the input region to any of the plurality of output regions other than the corresponding one of the plurality of output regions is −30 dB or less, −22 dB or less, or otherwise. For example, if channel 1 of a multi-channel optical signal is mapped to output region 308, then the adverse power transmission from input region 302 to any other one of the plurality of output regions (e.g., output region 310, output region 312, output region 314) other than the corresponding one of the plurality of output regions (e.g., output region 308) is −30 dB or less, −22 dB or less, or otherwise. In some embodiments, a maximum power reflection from demultiplexer 316 of an input signal (e.g., a multi-channel optical signal) received at an input region (e.g., input region 302) is reflected back to the input region by dispersive region 332 or otherwise is −40 dB or less, −20 dB or less, −8 dB or less, or otherwise. It is appreciated that in other embodiments the power transmission, adverse power transmission, maximum power, or other performance characteristics may be different than the respective values discussed herein, but the structure of dispersive region 332 may change due to the intrinsic relationship between structure, functionality, and performance of demultiplexer 316.

FIG. 3B illustrates a vertical schematic or stack of various layers that are included in the illustrated embodiment of demultiplexer 316. However, it is appreciated that the illustrated embodiment is not exhaustive and that certain features or elements may be omitted to avoid obscuring certain aspects of the invention. In the illustrated embodiment, demultiplexer 316 includes substrate 334, dielectric layer 336, active layer 338 (e.g., as shown in the cross-sectional illustration of FIG. 3A), and a cladding layer 340. In some embodiments, demultiplexer 316 may be, in part or otherwise, a photonic integrated circuit or silicon photonic device that is compatible with conventional fabrication techniques (e.g., lithographic techniques such as photolithographic, electron-beam lithography and the like, sputtering, thermal evaporation, physical and chemical vapor deposition, and the like).

In one embodiment a silicon on insulator (SOI) wafer may be initially provided that includes a support substrate (e.g., a silicon substrate) that corresponds to substrate 334, a silicon dioxide dielectric layer that corresponds to dielectric layer 336, a silicon layer (e.g., intrinsic, doped, or otherwise), and a oxide layer (e.g., intrinsic, grown, or otherwise). In one embodiment, the silicon in the active layer 338 may be etched selectively by lithographically creating a pattern on the SOI wafer that is transferred to SOI wafer via a dry etch process (e.g., via a photoresist mask or other hard mask) to remove portions of the silicon. The silicon may be etched all the way down to dielectric layer 336 to form voids that may subsequently be backfilled with silicon dioxide that is subsequently encapsulated with silicon dioxide to form cladding layer 340. In one embodiment, there may be several etch depths including a full etch depth of the silicon to obtain the targeted structure. In one embodiment, the silicon may be 206 nm thick and thus the full etch depth may be 206 nm. In some embodiments, this may be a two-step encapsulation process in which two silicon dioxide depositions are performed with an intermediate chemical mechanical planarization used to yield a planar surface.

FIG. 3C illustrates a more detailed view of active layer 338 (relative to FIG. 3B) taken along a portion of periphery region 318 that includes input region 302 of FIG. 3A. In the illustrated embodiment, active layer 338 includes a first material 342 with a refractive index of ε₁ and a second material 344 with a refractive index of ε₂ that is different from ε₁. Homogenous regions of the first material 342 and the second material 344 may form waveguides or portions of waveguides that correspond to input region 302 and plurality of output regions 304 as illustrated in FIG. 3A and FIG. 3C.

FIG. 3D illustrates a more detailed view of active layer 338 (relative to FIG. 3B) taken along dispersive region 332. As described previously, active layer 338 includes a first material 342 (e.g., silicon) and a second material 344 (e.g., silicon dioxide) that are inhomogeneously interspersed to form a plurality of interfaces 346 that collectively form a material interface pattern. Each of the plurality of interfaces 346 that form the interface pattern correspond to a change in refractive index of dispersive region 332 to structure the dispersive region (i.e., the shape and arrangement of first material 342 and second material 344) to provide, at least in part, the functionality of demultiplexer 316 (i.e., optical separation of the plurality of distinct wavelength channels from the multi-channel optical signal and respective guidance of each of the plurality of distinct wavelength channels to the corresponding one of the plurality of output regions 304 when the input region 302 receives the multi-channel optical signal).

It is appreciated that in the illustrated embodiments of demultiplexer 316 as shown in FIG. 3A-FIG. 3D, the change in refractive index is shown as being vertically consistent (i.e., the first material 342 and second material 344 form interfaces that are substantially vertical or perpendicular to a lateral plane or cross-section of demultiplexer 316. However, in the same or other embodiments, the plurality of interfaces (e.g., interfaces 346 illustrated in FIG. 3D) may not be substantially perpendicular with the lateral plane or cross-section of demultiplexer 316.

FIG. 4A illustrates a more detailed cross-sectional view of a dispersive region of example photonic demultiplexer 400, in accordance with an embodiment of the present disclosure. FIG. 4B illustrates a more detailed view of an interface pattern formed by the shape and arrangement of a first material 410 and a second material 412 for the dispersive region of the photonic demultiplexer 400 of FIG. 4A. Photonic demultiplexer 400 is one possible implementation of MUX/DEMUX 114 illustrated in FIG. 1, demultiplexer 206 illustrated in FIG. 2A, and demultiplexer 316 illustrated in FIG. 3A-FIG. 3D.

As illustrated in FIG. 4A and FIG. 4B, photonic demultiplexer 400 includes an input region 402, a plurality of output regions 404a-404d, and a dispersive region 406 optically disposed between input region 402 and plurality of output regions 404a-404d. Dispersive region 406 is surrounded, at least in part, by a peripheral region 408 that includes an inner boundary 414 and an outer boundary 416. It is appreciated that like named or labeled elements of photonic demultiplexer 400 may similarly correspond to like named or labeled elements of other demultiplexers described in embodiments of the present disclosure.

The first material 410 (i.e., black colored regions within dispersive region 406) and second material 412 (i.e., white colored regions within dispersive region 406) of photonic demultiplexer 400 are inhomogeneously interspersed to create a plurality of interfaces that collectively form material interface pattern 420 as illustrated in FIG. 4B. More specifically, an inverse design process that utilizes iterative gradient-based optimization, Markov Chain Monte Carlo optimization, or other optimization techniques combined with first principles simulations to generate a design that is substantially replicated by dispersive region 406 within a proportional or scaled manner such that photonic demultiplexer 400 provides the desired functionality. In the illustrated embodiment, dispersive region 406 is structured to optically separate each of a plurality of distinct wavelength channels from a multi-channel optical signal and respectively guide each of the plurality of distinct wavelength channels to a corresponding one of the plurality of output regions 404a-404d when the input region 402 receives the multi-channel optical signal. More specifically, the plurality of output regions 404a-404d are respectively mapped to wavelength channels having center wavelengths correspond to 1271 nm, 1291 nm, 1311 nm, and 1331 nm. In another embodiment, output regions 404a-404d are respectfully mapped to wavelength channels having center wavelengths that correspond to 1506 nm, 1514 nm, 1551 nm, and 1571 nm.

As illustrated in FIG. 4B, material interface pattern 420, which is defined by the black lines within dispersive region 406 and corresponds to a change in refractive index within dispersive region 406, includes a plurality of protrusions 422a-422b. A first protrusion 422a is formed of the first material 410 and extends from peripheral region 408 into dispersive region 406. Similarly, a second protrusion 422b is formed of the second material 412 and extends from peripheral region 408 into dispersive region 406. Further illustrated in FIG. 4B, dispersive region 406 includes a plurality of islands 424a-424b formed of either the first material 410 or the second material 412. The plurality of islands 424a-424b include a first island 424a that is formed of the first material 410 and is surrounded by the second material 412. The plurality of islands 424a-424b also includes a second island 424b that is formed of the second material 412 and is surrounded by the first material 410.

In some embodiments, material interface pattern 420 includes one or more dendritic shapes, wherein each of the one or more dendritic shapes are defined as a branched structure formed from first material 410 or second material 412 and having a width that alternates between increasing and decreasing in size along a corresponding direction. Referring back to FIG. 4A, for clarity, dendritic structure 418 is labeled with a white arrow having a black border. As can be seen, the width of dendritic structure 418 alternatively increases and decreases in size along a corresponding direction (i.e., the white labeled arrow overlaying a length of dendritic structure 418) to create a branched structure. It is appreciated that in other embodiments there may be no protrusions, there may be no islands, there may be no dendritic structures, or there may be any number, including zero, of protrusions, islands of any material included in the dispersive region 406, dendritic structures, or a combination thereof.

In some embodiments, the inverse design process includes a fabrication loss that enforces a minimum feature size, for example, to ensure fabricability of the design. In the illustrated embodiment of photonic demultiplexer 400 illustrated in FIG. 4A and FIG. 4B, material interface pattern 420 is shaped to enforce a minimum feature size within dispersive region 406 such that the plurality of interfaces within the cross-sectional area formed with first material 410 and second material 412 do not have a radius of curvature with a magnitude of less than a threshold size. For example, if the minimum feature size is 150 nm, the radius of curvature for any of the plurality of interfaces have a magnitude of less than the threshold size, which corresponds the inverse of half the minimum feature size (i.e., 1/75 nm⁻¹). Enforcement of such a minimum feature size prevents the inverse design process from generating designs that are not fabricable by considering manufacturing constraints, limitations, and/or yield. In the same or other embodiments, different or additional checks on metrics related to fabricability may be utilized to enforce a minimum width or spacing as a minimum feature size.

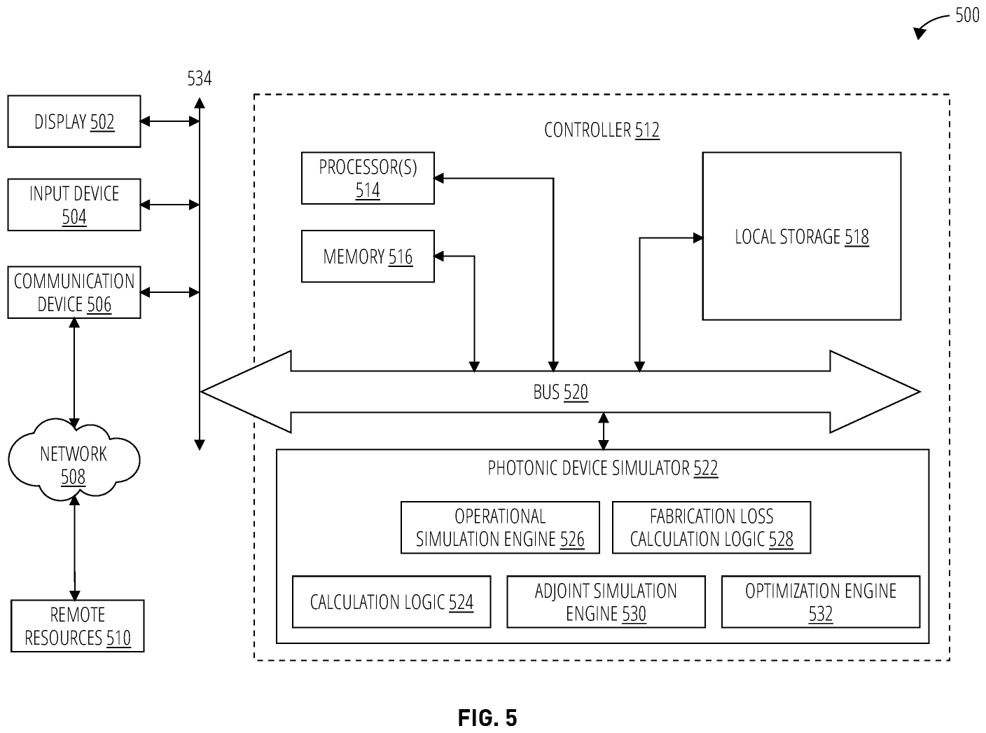

FIG. 5 is a functional block diagram illustrating a computing system 500 for generating a design of a photonic integrated circuit (i.e., photonic device), in accordance with an embodiment of the disclosure. Computing system 500 may be utilized to perform an inverse design process that generates a design with iterative gradient-based optimization that takes into consideration the underlying physics that govern the operation of the photonic integrated circuit. More specifically, computing system 500 is a design tool that may be utilized to optimize structural parameters (e.g., shape and arrangement of a first material and a second material within the dispersive region of the embodiments described in the present disclosure) of photonic integrated circuits based on first-principles simulations (e.g., electromagnetic simulations to determine a field response of the photonic device to an excitation source) and iterative gradient-based optimization. In other words, computing system 500 may provide a design obtained via the inverse design process that is substantially replicated (i.e., proportionally scaled) by dispersive region 332 and dispersive region 406 of demultiplexer 316 and photonic demultiplexer 400 illustrated in FIG. 3A and FIG. 4A, respectively.

As illustrated, computing system 500 includes controller 512, display 502, input device(s) 504, communication device(s) 506, network 508, remote resources 510, bus 534, and bus 520. Controller 512 includes processor 514, memory 516, local storage 518, and photonic device simulator 522. Photonic device simulator 522 includes operational simulation engine 526, fabrication loss calculation logic 528, calculation logic 524, adjoint simulation engine 530, and optimization engine 532. It is appreciated that in some embodiments, controller 512 may be a distributed system.

Controller 512 is coupled to display 502 (e.g., a light emitting diode display, a liquid crystal display, and the like) coupled to bus 534 through bus 520 for displaying information to a user utilizing computing system 500 to optimize structural parameters of the photonic device (i.e., demultiplexer). Input device 504 is coupled to bus 534 through bus 520 for communicating information and command selections to processor 514. Input device 504 may include a mouse, trackball, keyboard, stylus, or other computer peripheral, to facilitate an interaction between the user and controller 512. In response, controller 512 may provide verification of the interaction through display 502.

Another device, which may optionally be coupled to controller 512, is a communication device 506 for accessing remote resources 510 of a distributed system via network 508. Communication device 506 may include any of a number of networking peripheral devices such as those used for coupling to an Ethernet, Internet, or wide area network, and the like. Communication device 506 may further include a mechanism that provides connectivity between controller 512 and the outside world. Note that any or all of the components of computing system 500 illustrated in FIG. 5 and associated hardware may be used in various embodiments of the present disclosure. The remote resources 510 may be part of a distributed system and include any number of processors, memory, and other resources for optimizing the structural parameters of the photonic device.

Controller 512 orchestrates operation of computing system 500 for optimizing structural parameters of the photonic device. Processor 514 (e.g., one or more central processing units, graphics processing units, and/or tensor processing units, etc.), memory 516 (e.g., volatile memory such as DRAM and SRAM, non-volatile memory such as ROM, flash memory, and the like), local storage 518 (e.g., magnetic memory such as computer disk drives), and the photonic device simulator 522 are coupled to each other through bus 520. Controller 512 includes software (e.g., instructions included in memory 516 coupled to processor 514) and/or hardware logic (e.g., application specific integrated circuits, field-programmable gate arrays, and the like) that when executed by controller 512 causes controller 512 or computing system 500 to perform operations. The operations may be based on instructions stored within any one of, or a combination of, memory 516, local storage 518, physical device simulator 522, and remote resources 510 accessed through network 508.

In the illustrated embodiment, the components of photonic device simulator 522 are utilized to optimize structural parameters of the photonic device (e.g., MUX/DEMUX 114 of FIG. 1, demultiplexer 206 of FIG. 2A, multiplexer 208 of FIG. 2B, demultiplexer 316 of FIG. 3A-FIG. 3D, and photonic demultiplexer 400 of FIG. 4A-FIG. 4B). In some embodiments, computing system 500 may optimize the structural parameters of the photonic device via, inter alia, simulations (e.g., operational and adjoint simulations) that utilize a finite-difference time-domain (FDTD) method, a finite-difference frequency-domain (FDFD) method, or any other suitable technique to model the field response (e.g., electric and magnetic fields within the photonic device). The operational simulation engine 526 provides instructions for performing an electromagnetic simulation of the photonic device operating in response to an excitation source within a simulated environment. In particular, the operational simulation determines a field response of the simulated environment (and thus the photonic device, which is described by the simulated environment) in response to the excitation source for determining a performance metric of the physical device (e.g., based off an initial description or input design of the photonic device that describes the structural parameters of the photonic device within the simulated environment with a plurality of voxels). The structural parameters may correspond, for example, to the specific design, material compositions, dimensions, and the like of the physical device. Fabrication loss calculation logic 528 provides instructions for determining a fabrication loss, which is utilized to enforce a minimum feature size to ensure fabricability. In some embodiments, the fabrication loss is also used to enforce binarization of the design (i.e., such that the photonic device includes a first material and a second material that are interspersed to form a plurality of interfaces). Calculation logic 524 computes a loss metric determined via a loss function that incorporates a performance loss, based on the performance metric, and the fabrication loss. Adjoint simulation engine 530 is utilized in conjunction with the operational simulation engine 526 to perform an adjoint simulation of the photonic device to backpropagate the loss metric through the simulated environment via the loss function to determine how changes in the structural parameters of the photonic device influence the loss metric. Optimization engine 532 is utilized to update the structural parameters of the photonic device to reduce the loss metric and generate a revised description (i.e., revising the design) of the photonic device.

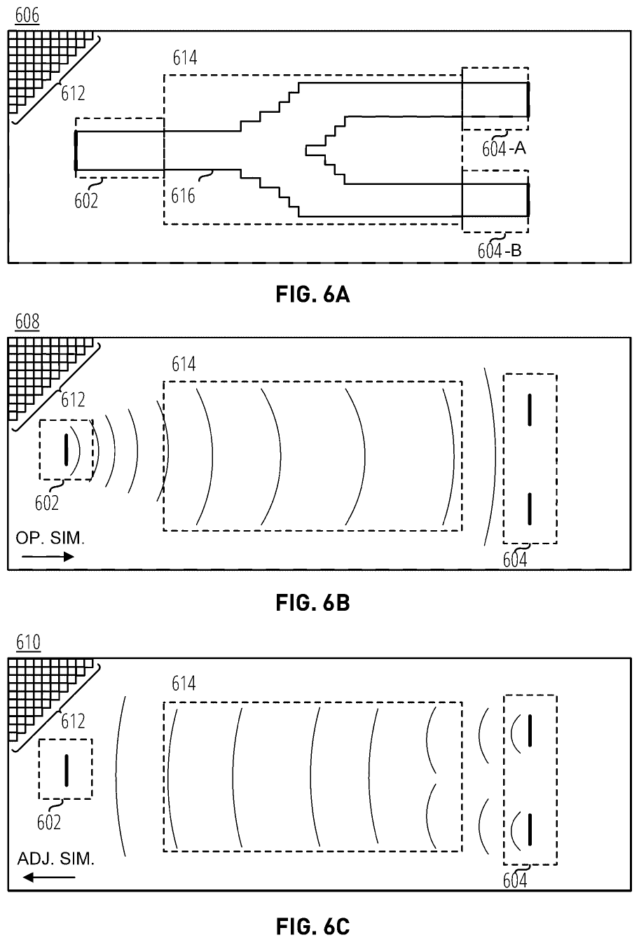

FIG. 6A-FIG. 6C respectively illustrate non-limiting example embodiments of an initial set up of a simulated environment 606 describing a photonic device, performing an operational simulation of the photonic device in response to an excitation source within the simulated environment 608, and performing an adjoint simulation of the photonic device within the simulated environment 610 according to various aspects of the present disclosure. The initial set up of the simulated environment, 1-dimensional representation of the simulated environment, operational simulation of the physical device, and adjoint simulation of the physical device may be implemented with computing system 500 illustrated in FIG. 5.

As illustrated in FIG. 6A-FIG. 6C, simulated environment is represented in two-dimensions. However, it is appreciated that other dimensionality (e.g., 3-dimensional space) may also be used to describe simulated environment and the photonic device. In some embodiments, optimization of structural parameters of the photonic device illustrated in FIG. 6A-FIG. 6C may be achieved via an inverse design process including, inter alia, simulations (e.g., operational simulations and adjoint simulations) that utilize a finite-difference time-domain (FDTD) method, a finite-difference frequency-domain (FDFD) method, or any other suitable technique to model the field response (e.g., electric and magnetic field) to an excitation source.

FIG. 6A illustrates a demonstrative simulated environment 606 describing a photonic integrated circuit (i.e., a photonic device such as a waveguide, demultiplexer, and the like), in accordance with a non-limiting example embodiment of the present disclosure. More specifically, in response to receiving an initial description of a photonic device defined by one or more structural parameters (e.g., an input design), a system (e.g., computing system 500 of FIG. 5) configures a simulated environment 606 to be representative of the photonic device. As illustrated, the simulated environment 606 (and subsequently the photonic device) is described by a plurality of voxels 612, which represent individual elements (i.e., discretized) of the two-dimensional (or other dimensionality) space. Each of the voxels 612 is illustrated as a two-dimensional square; however, it is appreciated that the voxels may be represented as cubes or other shapes in three-dimensional space. It is appreciated that the specific shape and dimensionality of the plurality of voxels 612 may be adjusted dependent on the simulated environment 606 and photonic device being simulated. It is further noted that only a portion of the plurality of voxels 612 are illustrated to avoid obscuring other aspects of the simulated environment 606.

Each of the plurality of voxels 612 may be associated with a structural value, a field value, and a source value. Collectively, the structural values of the simulated environment 606 describe the structural parameters of the photonic device. In one embodiment, the structural values may correspond to a relative permittivity, permeability, and/or refractive index that collectively describe structural (i.e., material) boundaries or interfaces of the photonic device (e.g., material interface pattern 420 of FIG. 4B). For example, an interface 616 is representative of where relative permittivity changes within the simulated environment 606 and may define a boundary of the photonic device where a first material meets or otherwise interfaces with a second material. The field value describes the field (or loss) response that is calculated (e.g., via Maxwell's equations) in response to an excitation source described by the source value. The field response, for example, may correspond to a vector describing the electric and/or magnetic fields (e.g., in one or more orthogonal directions) at a particular time step for each of the plurality of voxels 612. Thus, the field response may be based, at least in part, on the structural parameters of the photonic device and the excitation source.

In the illustrated embodiment, the photonic device corresponds to an optical demultiplexer having a design region 614 (e.g., corresponding to dispersive region 332 of FIG. 3A, and/or dispersive region 406 of FIG. 4A), in which structural parameters of the physical device may be updated or otherwise revised. More specifically, through an inverse design process, iterative gradient-based optimization of a loss metric determined from a loss function is performed to generate a design of the photonic device that functionally causes a multi-channel optical signal to be demultiplexed and guided from input port 602 to a corresponding one of the output ports 604. Thus, input port 602 (e.g., corresponding to input region 302 of FIG. 3A, input region 402 of FIG. 4A, and the like) of the photonic device corresponds to a location of an excitation source to provide an output (e.g., a Gaussian pulse, a wave, a waveguide mode response, and the like). The output of the excitation source interacts with the photonic device based on the structural parameters (e.g., an electromagnetic wave corresponding to the excitation source may be perturbed, retransmitted, attenuated, refracted, reflected, diffracted, scattered, absorbed, dispersed, amplified, or otherwise as the wave propagates through the photonic device within simulated environment 606). In other words, the excitation source may cause the field response of the photonic device to change, which is dependent on the underlying physics governing the physical domain and the structural parameters of the photonic device. The excitation source originates or is otherwise proximate to input port 602 and is positioned to propagate (or otherwise influence the field values of the plurality of voxels) through the design region 614 towards output ports 604 of the photonic device. In the illustrated embodiment, the input port 602 and output ports 604 are positioned outside of the design region 614. In other words, in the illustrated embodiment, only a portion of the structural parameters of the photonic device is optimizable.

However, in other embodiments, the entirety of the photonic device may be placed within the design region 614 such that the structural parameters may represent any portion or the entirety of the design of the photonic device. The electric and magnetic fields within the simulated environment 606 (and subsequently the photonic device) may change (e.g., represented by field values of the individual voxels that collectively correspond to the field response of the simulated environment) in response to the excitation source. The output ports 604 of the optical demultiplexer may be used for determining a performance metric of the photonic device in response to the excitation source (e.g., power transmission from input port 602 to a specific one of the output ports 604). The initial description of the photonic device, including initial structural parameters, excitation source, performance parameters or metrics, and other parameters describing the photonic device, are received by the system (e.g., computing system 500 of FIG. 5) and used to configure the simulated environment 606 for performing a first-principles based simulation of the photonic device. These specific values and parameters may be defined directly by a user (e.g., of computing system 500 in FIG. 5), indirectly (e.g., via controller 512 culling pre-determined values stored in memory 516, local storage 518, or remote resources 510), or a combination thereof.

FIG. 6B illustrates a non-limiting example embodiment of an operational simulation of the photonic device in response to an excitation source within simulated environment 608, in accordance with various aspects of the present disclosure. In the illustrated embodiment, the photonic device is an optical demultiplexer structured to optically separate each of a plurality of distinct wavelength channels included in a multi-channel optical signal received at input port 602 and respectively guide each of the plurality of distinct wavelength channels to a corresponding one of the plurality of output ports 604. The excitation source may be selected (randomly or otherwise) from the plurality of distinct wavelength channels and originates at input port 602 having a specified spatial, phase, and/or temporal profile. The operational simulation occurs over a plurality of time steps, including the illustrated time step. When performing the operational simulation, changes to the field response (e.g., the field value) for each of the plurality of voxels 612 are incrementally updated in response to the excitation source over the plurality of time steps. The changes in the field response at a particular time step are based, at least in part, on the structural parameters, the excitation source, and the field response of the simulated environment 610 at the immediately prior time step included in the plurality of time steps. Similarly, in some embodiments the source value of the plurality of voxels 612 is updated (e.g., based on the spatial profile and/or temporal profile describing the excitation source). It is appreciated that the operational simulation is incremental and that the field values (and source values) of the simulated environment 610 are updated incrementally at each time step as time moves forward for each of the plurality of time steps during the operational simulation. It is further noted that in some embodiments, the update is an iterative process and that the update of each field and source value is based, at least in part, on the previous update of each field and source value.

Once the operational simulation reaches a steady state (e.g., changes to the field values in response to the excitation source substantially stabilize or reduce to negligible values) or otherwise concludes, one or more performance metrics may be determined. In one embodiment, the performance metric corresponds to the power transmission at a corresponding one of the output ports 604 mapped to the distinct wavelength channel being simulated by the excitation source. In other words, in some embodiments, the performance metric represents power (at one or more frequencies of interest) in the target mode shape at the specific locations of the output ports 604. A loss value or metric of the input design (e.g., the initial design and/or any refined design in which the structural parameters have been updated) based, at least in part, on the performance metric may be determined via a loss function. The loss metric, in conjunction with an adjoint simulation, may be utilized to determine a structural gradient (e.g., influence of structural parameters on loss metric) for updating or otherwise revising the structural parameters to reduce the loss metric (i.e. increase the performance metric). It is noted that the loss metric may be further based on a fabrication loss value that is utilized to enforce a minimum feature size of the photonic device to promote fabricability of the device, and/or other loss values.

FIG. 6C illustrates a non-limiting example embodiment of an adjoint simulation within simulated environment 610 by backpropagating a loss metric, in accordance with various aspects of the present disclosure. More specifically, the adjoint simulation is a time-backwards simulation in which a loss metric is treated as an excitation source that interacts with the photonic device and causes a loss response. In other words, an adjoint (or virtual source) based on the loss metric is placed at the output region (e.g., output ports 604) or other location that corresponds to a location used when determining the performance metric. The adjoint source(s) is then treated as a physical stimuli or an excitation source during the adjoint simulation. A loss response of the simulated environment 608 is computed for each of the plurality of time steps (e.g., backwards in time) in response to the adjoint source. The loss response collectively refers to loss values of the plurality of voxels 612 that are incrementally updated in response to the adjoint source over the plurality of time steps. The change in loss response based on the loss metric may correspond to a loss gradient, which is indicative of how changes in the field response of the physical device influence the loss metric. The loss gradient and the field gradient may be combined in the appropriate way to determine a structural gradient of the photonic device/simulated environment (e.g., how changes in the structural parameters of the photonic device within the simulated environment influence the loss metric). Once the structural gradient of a particular cycle (e.g., operational and adjoint simulation) is known, the structural parameters may be updated to reduce the loss metric and generate a revised description or design of the photonic device.

In some embodiments, iterative cycles of performing the operational simulation, and adjoint simulation, determining the structural gradient, and updating the structural parameters to reduce the loss metric are performed successively as part of an inverse design process that utilizes iterative gradient-based optimization. An optimization scheme such as gradient descent may be utilized to determine specific amounts or degrees of changes to the structural parameters of the photonic device to incrementally reduce the loss metric. More specifically, after each cycle the structural parameters are updated (e.g., optimized) to reduce the loss metric. The operational simulation, adjoint simulation, and updating the structural parameters are iteratively repeated until the loss metric substantially converges or is otherwise below or within a threshold value or range such that the photonic device provides the desired performed while maintaining fabricability.

In previous techniques, the designs for a physical device may be parameterized directly using voxels 612 to represent both an initial design and structural parameters to be simulated within the simulated environment. While voxel-based parameterization can lead to non-intuitive and detailed designs such as those illustrated in FIG. 4A and FIG. 4B, the computational complexity introduced by this parameterization in performing tasks such as checking for fabricability and applying gradient-based updates can make their use cost-prohibitive in terms of both time and computing resource requirements. In some embodiments, simple parameterizations may be used that can more easily be optimized than a voxel-based parameterization that directly represents the structural parameters of the physical device at each location.

In some embodiments of the present disclosure, instead of using a voxel-based parameterization that requires evaluation of each voxel in the design, features included in the design for the physical device are parameterized using one or more geometric shape primitives, where each geometric shape primitive is large in comparison to the voxels of the structural parameters. By using significantly fewer parameterized features than the voxels of the structural parameters, the computing resources used to optimize the design are greatly reduced. Further, it has been found that the use of features parameterized using geometric shape primitives can cause the performance loss value to converge after fewer iterations of the optimization loop compared to the more detailed voxel-based parameterization.

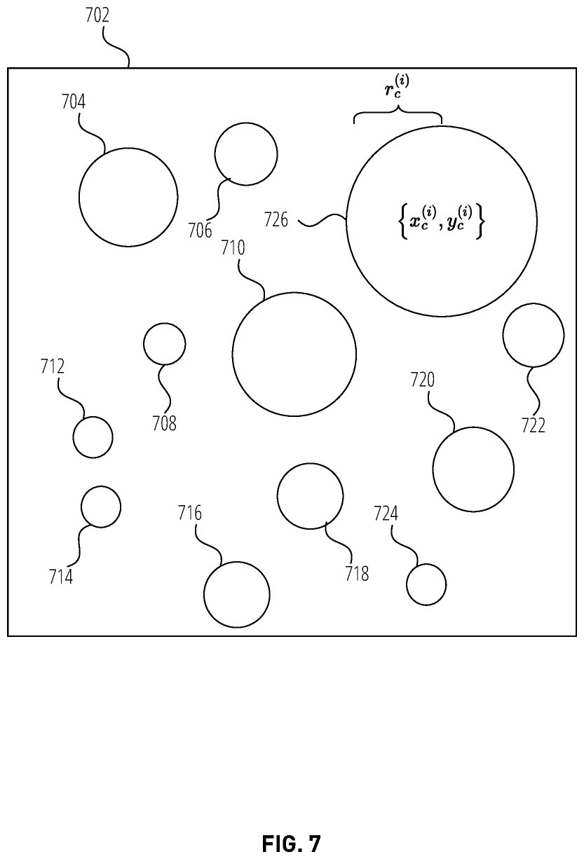

FIG. 7 is a schematic illustration of a non-limiting example embodiment of a parameterization of features for a design of a physical device that uses geometric shape primitives, according to various aspects of the present disclosure. In FIG. 7, the design includes a design region 702, and features within the design region 702 are described by a plurality of geometric shape primitives 704-726. One will recognize that the design that includes the illustrated design region 702 may include other features, including but not limited to one or more input ports and/or one or more output ports. These features are illustrated in other drawings, but have not been illustrated in FIG. 7 to avoid obscuring other aspects of the disclosed subject matter.

In the illustrated embodiment, the features are represented by geometric shape primitives 704-726 that are circles. In other embodiments, features may be represented using other techniques including but not limited to other types of geometric shape primitives, including but not limited to rectangles, higher-order polygons, or other types of geometric shape primitives. As will be seen, using circles (or other simple geometric shapes) as the geometric shape primitives 704-726 can lead to various efficiencies. For example, each of the geometric shape primitives 704-726 can be defined uniquely within the design region 702 with a small number of data points. The geometric shape primitive 726 is labeled with its defining data points: coordinates of a center of the geometric shape primitive 726 within a plane of the design region 702, illustrated as { [symbol] , [symbol] }, and a radius of the geometric shape primitive 726, illustrated as [symbol] . As can be seen, the entire geometric shape primitive 726 can be represented with three scalar values. This is a vast improvement over the voxel-based parameterization, in which each voxel within the geometric shape primitive 726 would be represented with its own value.

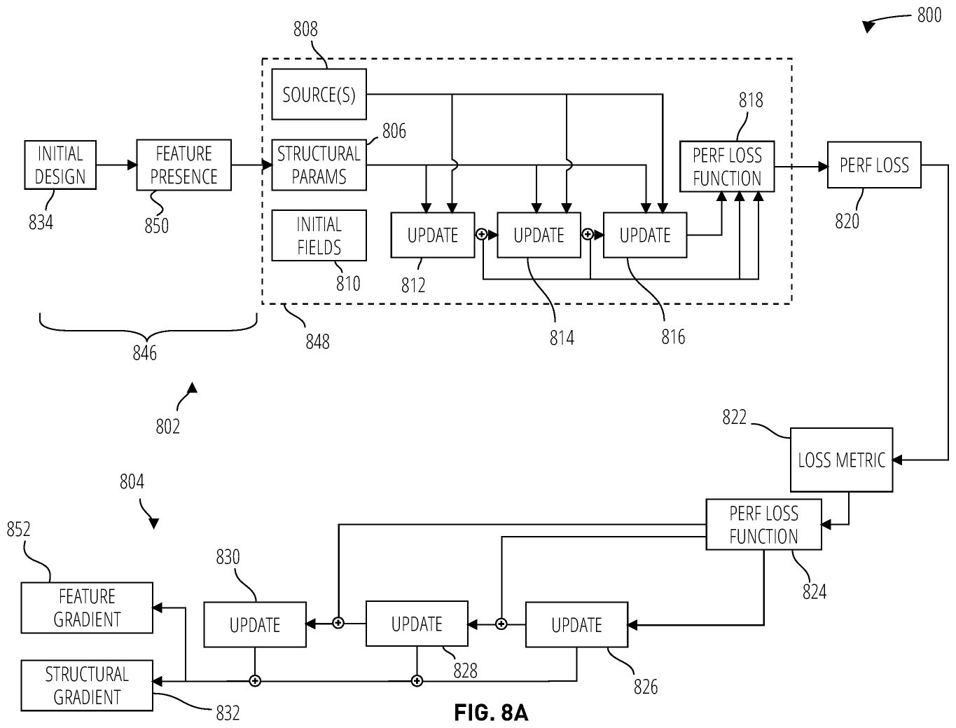

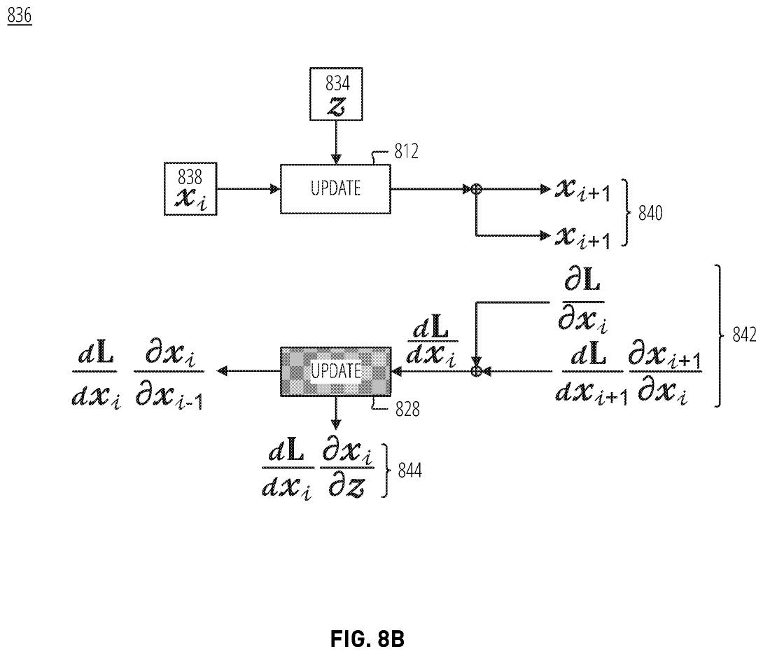

FIG. 8A is a flow chart 800 illustrating example time steps for an operational simulation 802 and an adjoint simulation 804, in accordance with various aspects of the present disclosure. Flow chart 800 is one possible implementation that a system may use to perform the operational simulation 802 and adjoint simulation 804 of the simulated environment describing a photonic integrated circuit (e.g., an optical device operating in an electromagnetic domain such a photonic demultiplexer). In the illustrated embodiment, the operational simulation 802 utilizes a finite-difference time-domain (FDTD) method, a finite-difference frequency-domain (FDFD) method, or any other suitable technique to model the field response (both electric and magnetic) or loss response at each of a plurality of voxels for a plurality of time steps in response to physical stimuli corresponding to an excitation source and/or adjoint source.

As illustrated in FIG. 8A, the operational simulation 802 includes a configuration portion 846 and a simulation portion 848. In the configuration portion 846, an initial design 834 is generated that is based on a design specification. In some embodiments, the design specification sets out one or more goals of the inverse design process, such as by providing expected performance characteristics and/or initial locations for one or more input ports, expected performance characteristics and/or initial locations for one or more output ports, a size of a design region, allowable locations for input ports and/or output ports, an initial number of features to be included in the design region, fabrication constraints (including but not limited to one or more of a minimum feature size, a minimum distance between features, or a boundary buffer).

In some embodiments, the initial design 834 includes a parameterization of the design. The parameters representing the design are optimized by the remainder of the operational simulation 802 and the adjoint simulation 804 in order to generate a design for the physical device that is highly performant. One non-limiting example parameterization is the voxel-based parameterization illustrated in FIG. 6A-FIG. 6C and described above. Another non-limiting example parameterization is a geometric shape primitive parameterization, such as the circular geometric shape primitive parameterization illustrated in FIG. 7 and described above.

It is appreciated that the initial design 834 may be a relative term. Thus, in some embodiments an initial design 834 may be a first description of the physical device described within the context of the simulated environment (e.g., a first input design for performing a first operational simulation). However, in other embodiments, the term initial design 834 may refer to an initial design 834 of a particular iteration of an optimization loop (e.g., of performing an operational simulation 802, operating an adjoint simulation 804, and updating the structural parameters). In such an embodiment, the initial design 834 or design of that particular cycle may correspond to a revised description or refined design (e.g., generated from a previous cycle). In some embodiments, the simulated environment includes a design region that includes a portion of the plurality of voxels which have structural parameters that may be updated, revised, or otherwise changed to optimize the structural parameters of the physical device. In the same or other embodiments, the structural parameters are associated with geometric boundaries and/or material compositions of the physical device based on the material properties (e.g., relative permittivity, index of refraction, etc.) of the simulated environment.

In some embodiments, after determining the initial design 834, the operational simulation 802 generates a set of structural parameters 806 to be simulated within the simulated environment. Typically, the initial design 834 is provided as a list of features (e.g., a list of geometric shape primitives as discussed above), and the simulated environment uses a set of structural parameters such as the voxels 612 illustrated in FIG. 6A-FIG. 6C. Accordingly, the operational simulation 802 uses the list of features to generate the structural parameters 806 for the operational simulation.

As stated above, the design specification may indicate a number of features to be included in the initial design 834. However, one difficult aspect of optimizing the initial design 834 is that the number of features indicated by the design specification may not be an optimal number of features to be included. For example, the number of features indicated by the design specification may be greater than an optimal number of features. As such, it is desirable to organize the optimization technique to account for changing the number of features included within the design.

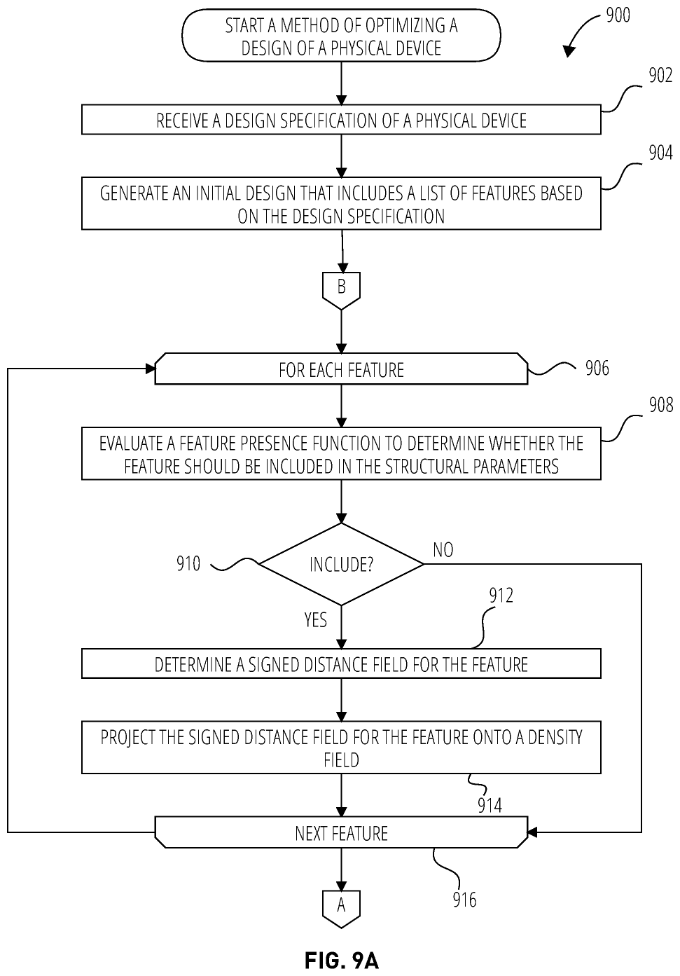

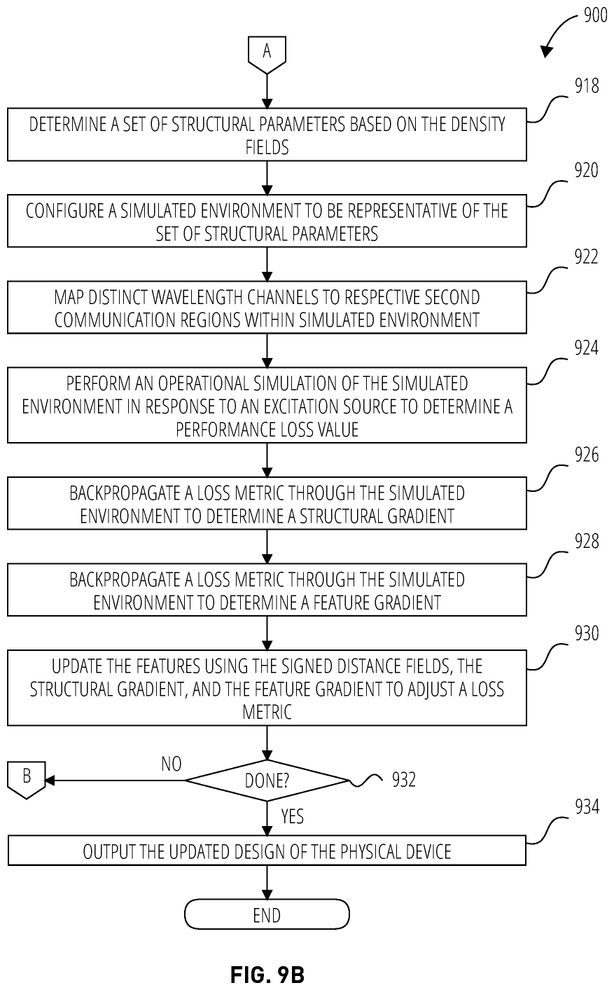

Accordingly, in some embodiments, the operational simulation 802 uses a feature presence function 850 to determine whether each feature of the list of features from the initial design 834 should be included within the set of structural parameters 806 to be simulated. If the feature presence function 850 indicates that a given feature should be included within the design, then the structural parameters 806 are adjusted to include the given feature. Likewise, if the feature presence function 850 does not indicate that the given feature should be included within the design, then given feature is ignored when updating the structural parameters 806. Further discussion of techniques for converting the initial design 834 to structural parameters 806 using a feature presence function 850 are illustrated and discussed with respect to FIG. 9A-FIG. 9B.

After the structural parameters 806 are determined, the operational simulation 802 proceeds to a simulation portion 848. The structural parameters 806 represent the physical structure of the physical device to be simulated, and may be represented by voxels 612 (or another format suitable for processing by the simulated environment) regardless of the specific parameterization provided by the initial design 834.

The simulation portion 848 occurs over a plurality of time-steps (e.g., from an initial time step to a final time step over a pre-determined or conditional number of time steps having a specified time step size) and models changes (e.g., from the initial field values 810) in electric and magnetic fields of a plurality of voxels describing the simulated environment and/or photonic device that collectively correspond to the field response. More specifically, update operations (e.g., update operation 812, update operation 814, and update operation 816) are iterative and based on the field response, structural parameters 806, and one or more excitation sources 808. Each update operation is succeeded by another update operation, which are representative of successive steps forward in time within the plurality of time steps. For example, update operation 814 updates the field values 838 (see, e.g., FIG. 8B) based on the field response determined from the previous update operation 812, excitation sources 808, and the structural parameters 806. Similarly, update operation 816 updates the field values 840 (see, e.g., FIG. 8B) based on the field response determined from update operation 814. In other words, at each time step of the operational simulation the field values (and thus field response) are updated based on the previous field response and structural parameters of the photonic device.

Once the final time step of the simulation portion 848 is performed, a performance loss function 818 is used to determine a performance loss value 820 associated with the initial design 834. In some embodiments, additional loss values, including but not limited to a fabrication loss value that is based on whether portions of the structural parameters 806 (and/or the initial design 834) are detected as violating one or more fabricability constraints, may be combined with the one or more performance loss values 820.

From the loss metric 822, loss gradients of the performance loss function may be determined at block 824. The loss gradients determined from block 824 may be treated as adjoint or virtual sources (e.g., physical stimuli or excitation source originating at an output region or port) which are backpropagated in reverse (from the final time step incrementally through the plurality of time steps until reaching the initial time step via update operation 826, update operation 830, and update operation 828) to determine a structural gradient 832. In some embodiments, a feature gradient 852 may also be determined based on the update operations. One aspect of a feature presence function 850 that either includes or excludes features is that this type of feature presence function 850 is poorly differentiable, if at all. In other words, there is a discontinuity in the feature presence function 850 around the region where the feature transitions from being included to being excluded. As such, gradients typically do not flow through the feature presence function 850 effectively in order to allow the number of features included in the design to be adjusted by the optimization process. Accordingly, a separate feature gradient 852 that is different from the feature presence function 850 may be used by the adjoint simulation 804 to update the values in the features that are used by the feature presence function 850. Further descriptions of the uses of the feature presence function 850 and the feature gradient 852 are provided below.

In the illustrated embodiment, the FDTD solve (e.g., simulation portion 848 of the operational simulation 802) and backward solve (e.g., adjoint simulation 804) problem are described pictorially, from a high-level, using only “update” and “loss” operations as well as their corresponding gradient operations. The simulation is set up initially in which the structural parameters, physical stimuli (i.e., excitation source), and initial field states of the simulated environment (and photonic device) are provided (e.g., via an initial description and/or input design). As discussed previously, the field values are updated in response to the excitation source based on the structural parameters. More specifically, the update operation is given by ϕ.

where [symbol] =ϕ( [symbol] , [symbol] ᵢ, [symbol] ) for [symbol] =1, . . . , [symbol] . Here, [symbol] corresponds to the total number of time steps (e.g., the plurality of time steps) for the operational simulation, where [symbol] corresponds to the field response (the field value associated with the electric and magnetic fields of each of the plurality of voxels) of the simulated environment at time step [symbol] , [symbol] corresponds to the excitation source(s) (the source value associated with the electric and magnetic fields for each of the plurality of voxels) of the simulated environment at time step [symbol] , and [symbol] corresponds to the structural parameters describing the topology and/or material properties of the physical device (e.g., relative permittivity, index of refraction, and the like).

It is noted that using the FDTD method, the update operation may specifically be stated as:

$$ϕ ( {x}_{i} , , z ) = A ( z ) {x}_{i} + B ( z )$$

That is to say the FDTD update is linear with respect to the field and source terms. Concretely, A( [symbol] )∈ [symbol] and B( [symbol] )∈ [symbol] are linear operators which depend on the structure parameters, [symbol] , and act on the fields, [symbol] , and the sources, [symbol] , respectively. Here, it is assumed that [symbol] , [symbol] ∈ [symbol] where N is the number of FDTD field components in the operational simulation. Additionally, the loss operation (e.g., loss function) may be given by L=f( [symbol] , . . . , [symbol] ₙ), which takes as input the computed fields and produces a single, real-valued scalar (e.g., the loss metric) that can be reduced and/or minimized.

In terms of revising or otherwise optimizing the structural parameters of the physical device, the relevant quantity to produce is dL/d [symbol] , which is used to describe the influence of changes in the structural parameters of the initial design 834 on the loss value and is denoted as the structural gradient 832 illustrated in FIG. 8A.

FIG. 8B is a chart 836 illustrating the relationship between the update operation for the operational simulation and the adjoint simulation (e.g., backpropagation), in accordance with an embodiment of the present disclosure. More specifically, FIG. 8B summarizes the operational and adjoint simulation relationships that are involved in computing the structural gradient, dL/d [symbol] , which include

$$\frac{\partial L}{\partial {x}_{i}} , \frac{\partial {x}_{i + 1}}{\partial {x}_{i}} , \frac{d L}{d {x}_{i}} , and \frac{\partial {x}_{i}}{{\partial }_{z}} .$$

The update operation 814 of the operational simulation 802 updates the field values 838, [symbol] , of the plurality of voxels at the [symbol] th time step to the next time step (i.e., [symbol] +1 time step), which correspond to the field values 840, [symbol] . The gradients 842 are utilized to determine ∂L/∂xᵢ for the backpropagation (e.g., update operation 830 backwards in time), which combined with the gradients 844 are used, at least in part, to calculate the structural gradient,

$$\frac{d L}{dz} . \frac{\partial L}{\partial {x}_{i}}$$

is the contribution of each field to the loss metric, L. It is noted that this is the partial derivative, and therefore does not take into account the causal relationship of [symbol] → [symbol] . Thus,

$$\frac{\partial {x}_{i + 1}}{\partial {x}_{i}}$$

is utilized which encompasses the [symbol] → [symbol] relationship. The loss gradient, dL/d [symbol] , may also be used to compute the structural gradient, dL/d [symbol] and corresponds to the total derivative of the field with respect to loss value, L. The loss gradient, dL/d [symbol] , at a particular time step, [symbol] , is equal to the summation of

$$\frac{\partial L}{\partial {x}_{i}} + \frac{d L}{d {x}_{i + 1}} \frac{\partial {x}_{i + 1}}{\partial {x}_{i}} .$$

Finally, ∂xᵢ/∂ [symbol] , which corresponds to the field gradient, is used which is the contribution to dL/d [symbol] from each time/update step.

In particular, the memory footprint to directly compute

$$\frac{\partial L}{\partial {x}_{i}} and \frac{d L}{d z}$$

is so large that it is difficult to store more than a handful of state Tensors. The state Tensor corresponds to storing the values of all of the FDTD cells (e.g., the plurality of voxels) for a single simulation time step. It is appreciated that the term “tensor” may refer to tensors in a mathematical sense or as described by the TensorFlow framework developed by Alphabet, Inc. In some embodiments the term “tensor” refers to a mathematical tensor which corresponds to a multidimensional array that follows specific transformation laws. However, in most embodiments, the term “tensor” refers to TensorFlow tensors, in which a tensor is described as a generalization of vectors and matrices to potentially higher dimensions (e.g., n-dimensional arrays of base data types), and is not necessarily limited to specific transformation laws. For example, for the general loss function ƒ, it may be necessary to store the fields, [symbol] , for all time steps, [symbol] . This is because, for most choices of ƒ, the gradient will be a function of the arguments of ƒ. This difficulty is compounded by the fact that the values of ∂L/∂ [symbol] for larger values of [symbol] are needed before the values for smaller [symbol] due to the incremental updates of the field response and/or through backpropagation of the loss metric, which may prevent the use of schemes that attempt to store only the values ∂L/∂ [symbol] , at an immediate time step.

An additional difficulty is further illustrated when computing the structural gradient, dL/d [symbol] , which is given by:

$$\frac{d L}{dz} = {\sum }_{i} \frac{d L}{{dx}_{i}} \frac{\partial {x}_{i}}{\partial z} .$$

For completeness, the full form of the first term in the sum, dL/d [symbol] , is expressed as:

$$\frac{d L}{d {x}_{i}} = \frac{\partial L}{\partial {x}_{i}} + \frac{dL}{d {x}_{i + 1}} \frac{\partial {x}_{i + 1}}{\partial {x}_{i}}$$

Based on the definition of ϕ as described by equation (1), it is noted that

$$\frac{\partial {x}_{i + 1}}{\partial {x}_{i}} = A ( z ) ,$$

which can be substituted in equation (3) to arrive at an adjoint update for backpropagation (e.g., the update operations such as update operation 830), which can be expressed as:

$$\frac{d L}{d {x}_{i}} = \frac{\partial L}{\partial {x}_{i}} + \frac{d L}{d {x}_{i + 1}} A ( z ) ,$$

$$or {∇}_{{x}_{i}} L = {A ( z )}^{T} {∇}_{{x}_{i + 1}} L + \frac{\partial {L}^{T}}{\partial {x}_{i}}$$

The adjoint update is the backpropagation of the loss gradient (e.g., from the loss metric) from later to earlier time steps and may be referred to as a backwards solve for dL/d [symbol] . More specifically, the loss gradient may initially be based upon the backpropagation of a loss metric determined from the operational simulation with the loss function. The second term in the sum of the structural gradient, dL/d [symbol] , corresponds to the field gradient and is denoted as:

$$\frac{\partial {x}_{i}}{\partial z} = \frac{d ϕ ( {x}_{i - 1} , , z )}{d z} = \frac{d A ( z )}{dz} {x}_{i - 1} + \frac{d B ( z )}{d z} ,$$

for the particular form of ϕ described by the first equation above. Thus, each term of the sum associated dL/d [symbol] depends on both

$$\frac{d L}{{dx}_{{i}_{0}}} for i \geq {i}_{0} and {x}_{{i}_{0}} for i < {i}_{0} .$$

Since the dependency chains of these two terms are in opposite directions, it is concluded that computing dL/d [symbol] in this way requires the storage of [symbol] values for all of [symbol] . In some embodiments, the need to store all field values may be mitigated by a reduced representation of the fields.

FIG. 9A is a flowchart that illustrates a non-limiting example embodiment of a method 900 for generating a design of physical device such as a photonic integrated circuit that allows an optimizer to adjust a number of included features, in accordance with various aspects of the present disclosure.

It is appreciated that method 900 is an inverse design process that may be accomplished by performing operations with a system to perform iterative gradient-based optimization of a loss metric determined from a loss function that includes at least a performance loss, similar to that illustrated and described in FIG. 8A and FIG. 8B. In the same or other embodiments, method 900 may be included as instructions provided by at least one machine-accessible storage medium (e.g., non-transitory memory) that, when executed by a machine, will cause the machine to perform operations for generating and/or improving the design of the physical device. It is further appreciated that the order in which some or all of the process blocks appear in method 900 should not be deemed limiting. Rather, one of ordinary skill in the art having the benefit of the present disclosure will understand that some of the process blocks may be executed in a variety of orders not illustrated, and/or in parallel.

From a start block, the method 900 proceeds to block 902, where a design specification of a physical device such as a photonic integrated circuit is received. In some embodiments, the physical device may be expected to have a certain functionality (e.g., perform as an optical demultiplexer, an optical multiplexer, an optical waveguide bend, or another type of optoelectronic component) after optimization. In some embodiments, the design specification may indicate an overall structure of the physical device (e.g., dimensions of a design region, initial locations and numbers of one or more input ports and/or one or more output ports), desired performance of the device (e.g., desired performance characteristics at each input port and/or output port), one or more fabricability constraints (e.g., a minimum feature size, a minimum distance, a boundary buffer size, etc.) associated with a fabrication system (e.g., a photolithography system or collection of systems that includes a photolithography system) to be used to fabricate the physical device, a starting number of features to be included in a list of features, and/or any other relevant specification.

At block 904, an initial design 834 is generated that includes a list of features based on the design specification. In some embodiments, the features of the list of features may be specified using geometric shape primitives. In some embodiments, the type of geometric shape primitive (e.g., circle, square, rectangle, higher-order polygon, etc.) may be indicated by the design specification. In some embodiments, a number of geometric shape primitives to be included in the initial design 834 may be indicated in the design specification. In some embodiments, the geometric shape primitives may be randomly sized and randomly positioned within the design region of the initial design 834. In some embodiments, the geometric shape primitives of the initial design 834 may be of a default size and/or positioned at default or regular positions within the design region of the initial design 834. In some embodiments, the geometric shape primitives of the initial design 834 may be arranged to comply with the fabricability constraints associated with the fabrication system. In some embodiments, the geometric shape primitives may be arranged regardless of the fabricability constraints, with fabricability to be achieved during the optimization process.

Once the initial design 834 is generated at block 904, the method 900 advances through a continuation terminal (“terminal B”) to a for-loop defined between a for-loop start block 906 and a for-loop end block 916. In the for-loop, each feature in the list of features is processed to either be added to the structural parameters or ignored based on the feature presence function 850.

To process a feature, the method 900 advances from the for-loop start block 906 to block 908, where a feature presence function 850 is evaluated for the feature to determine whether the feature should be included in the structural parameters 806. In some embodiments, an input to the feature presence function 850 is some aspect of the parameterization of the feature, such as a size of the feature. In some embodiments, an input to the feature presence function 850 may be a scalar value associated with the feature that represents the feature presence and that may be separately optimized from the size and/or shape of the feature itself.

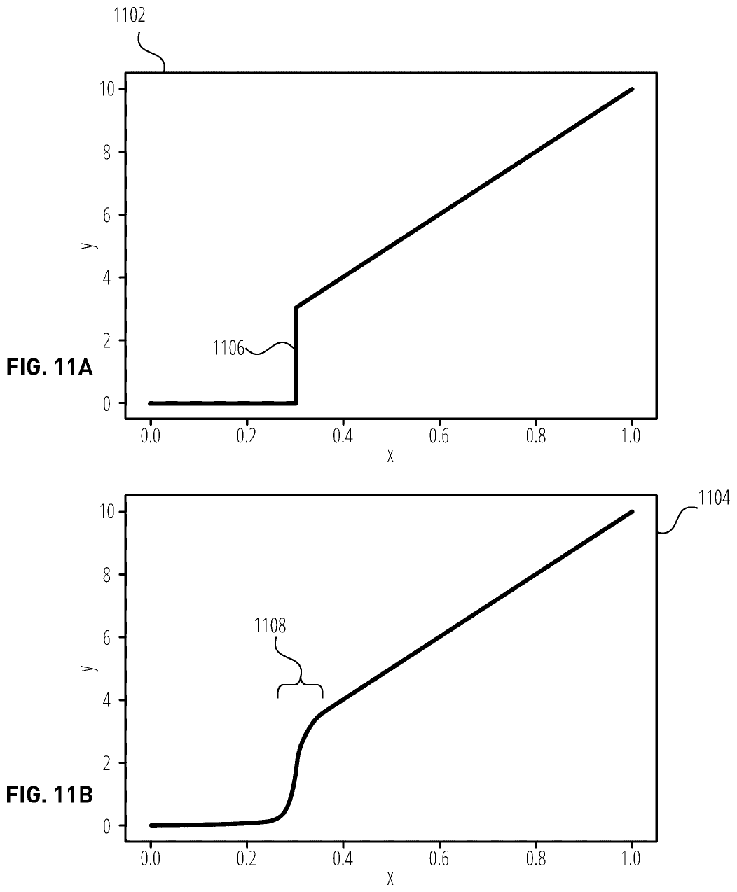

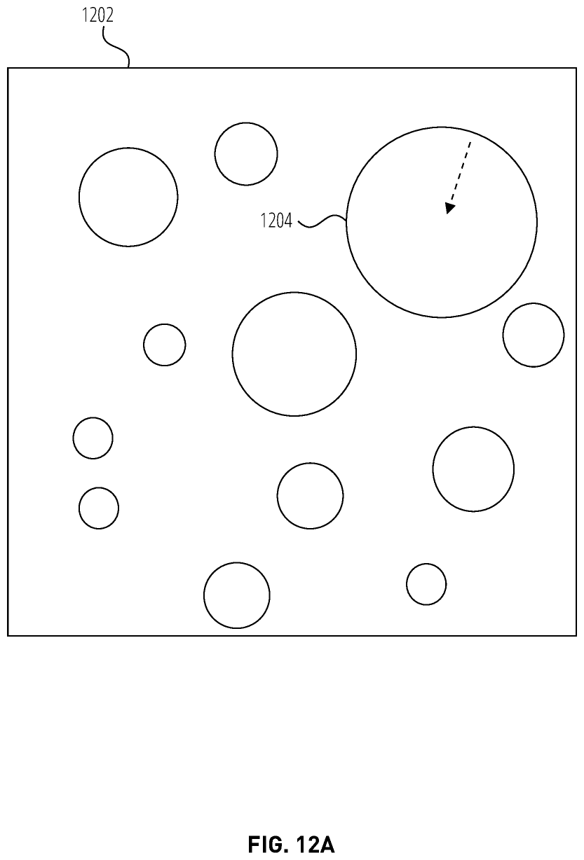

FIG. 11A is a chart that illustrates a non-limiting example embodiment of a feature presence function 850 according to various aspects of the present disclosure. In the illustration of the feature presence function 1102, the X-axis represents a value of an input to the feature presence function 850 that may be optimized during the method 900. The Y-axis represents an output of the feature presence function 850 that indicates whether the feature should be included in the structural parameters 806, with all non-zero values indicating that the feature should be included. One non-limiting example statement of a feature presence function 850 such as feature presence function 1102 is:

$$f ( x ) = \{ \begin{matrix}{y}_{min} + ( {y}_{max} - {y}_{min} ) \times ( x - c ) / ( 1 - c ) , & where x \geq c \\ 0 , & where x < c\end{matrix}$$

where c is the location of the feature presence cutoff 1106.

One non-limiting example of potential values illustrated on the X-axis are feature sizes. In other words, if the features are parameterized using geometric shape primitives such as circles, the values on the X-axis may be radius values. The feature presence function 1102 would consider the radius of the circle (the value on the X-axis) to determine whether the circle should be included in the structural parameters 806. A feature presence cutoff 1106 may be positioned at the minimum feature size supported by the fabrication system. Accordingly, if the optimization of the size of the feature causes the radius of the circle to be smaller than the minimum feature size, the feature would no longer be included in the structural parameters 806.

One will note that while the feature presence function 850 is effective in providing a cutoff below which the feature will no longer be included in the structural parameters 806, the feature presence function 850 is poorly differentiable: the gradient at the feature presence cutoff 1106 is undefined, and the gradient at all values below the feature presence cutoff 1106 is zero. As such, the feature presence function 850 cannot itself be used for gradient-based optimization of the feature presence. A solution to this issue is illustrated in FIG. 11B and discussed in more detail below.

After evaluating the feature presence function 850, the method 900 advances to a decision block 910, where a determination is made regarding whether the feature should be included in the structural parameters 806 based on the result of the feature presence function 850. In some embodiments, the result of the feature presence function 850 may be compared to a threshold value to determine whether the feature should be included. In the non-limiting example feature presence function 1102 illustrated in FIG. 11A, any non-zero result may indicate that the feature should be included, while a zero-valued result may indicate that the feature should be ignored. If it is determined that the feature should be ignored, then the result of decision block 910 is NO, and the method 900 refrains from including the feature in the structural parameters 806 and advances to the for-loop end block 916.

Otherwise, if the determination at decision block 910 is that the feature should be included in the structural parameters 806, the method 900 advances to block 912. While using geometric shape primitives to parameterize the design region may greatly simplify the search space to be analyzed during the inverse design process, one problem arises in that the geometric shape primitives may themselves be poorly differentiable. In other words, while the number of parameters to be optimized for geometric shape primitives is much lower than if individual voxels within the design region are optimized, a gradient of the loss metric does not backpropagate well to the geometric shape primitives themselves due to their discrete (not continuous) nature, and so it may be desirable to use an intermediate, continuous representation to convert the geometric shape primitives to structural parameters to be simulated in order to improve differentiability. Accordingly, at block 912, a signed distance field is determined for each of the geometric shape primitives.

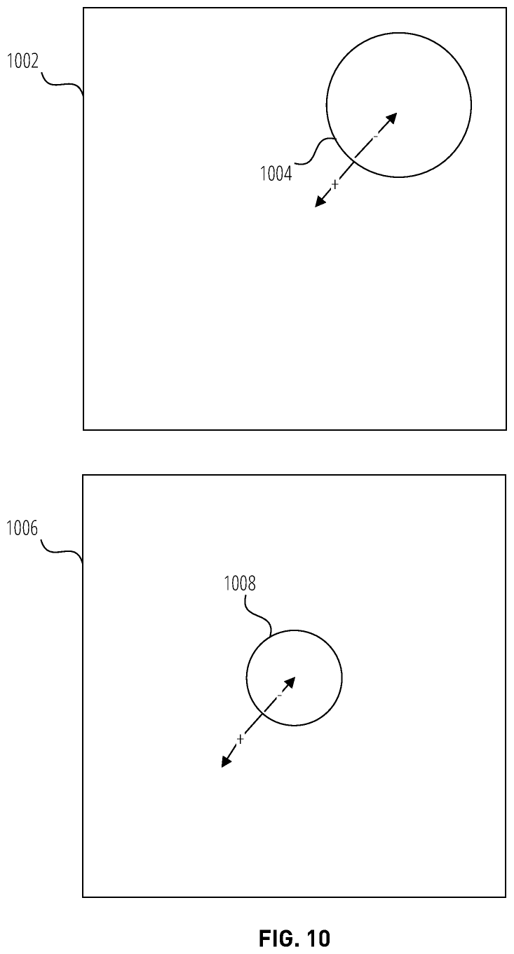

FIG. 10 includes schematic illustrations of a first signed distance field and a second signed distance field according to various aspects of the present disclosure. The first signed distance field 1002 and second signed distance field 1006 are non-limiting examples of signed distance fields for the geometric shape primitive 726 and geometric shape primitive 710, respectively, of the design region 702 illustrated in FIG. 7. In the first signed distance field 1002, increasingly negative values are assigned to areas on the interior of the first geometric shape primitive 1004, and increasingly positive values are assigned to areas on the exterior of the first geometric shape primitive 1004. Likewise, in the second signed distance field 1006, increasingly negative values are assigned to areas on the interior of the second geometric shape primitive 1008 and increasingly positive values are assigned to areas on the exterior of the second geometric shape primitive 1008. In some embodiments, real number values are used for the signed distance fields. As shown in FIG. 10, a separate signed distance field is created for each of the geometric shape primitives in the initial design 834.

In some embodiments, the signed distance field is determined analytically. For each voxel x, y within the signed distance field for a circular geometric shape primitive with a center x_{c}, y_{c} and radius r, the value of the voxel is given as:

$$SDF ( x , y ) = r - \sqrt{{\vert {x}_{c} - x \vert}^{2} + {\vert {y}_{c} - y \vert}^{2}}$$

It should be noted that though the first geometric shape primitive 1004, second signed distance field 1006, and second geometric shape primitive 1008 are illustrated in FIG. 10 for the sake of clarity, the zero-value contours in the signed distance fields are implicit, and the actual geometric shape primitives are not present in the signed distance fields.

In some embodiments, the features may be specified using other than a geometric shape primitive. In such embodiments, the features may still be represented by a signed distance field, such that a border of the feature is represented by a zero-value contour, and areas inside and outside of the border are increasingly negative or positive as discussed above. An analytic determination of the values of the signed distance field may also be used, or any other suitable technique for determining or specifying distances from the zero-value contour may be used.

Returning to FIG. 9A, at block 914, the signed distance field is projected onto a density field for the feature. In some embodiments, the density field may be of a size that matches the size of the design region and may include voxels similar to the voxels 612 of the simulated environment 606 illustrated above. Values at corresponding positions of the signed distance field may be added to the corresponding voxels of the density field.

Once the density field is generated for the feature, the method 900 advances to the for-loop end block 916. If additional features remain to be processed in the list of features, then the method 900 returns to for-loop start block 906 to process the next feature. Otherwise, the method 900 advances to a continuation terminal (“terminal A”).

From terminal A (FIG. 9B), the method 900 advances to block 918, where a set of structural parameters 806 is determined based on the density fields for each of the included features is determined. As a preliminary step, each of the separate density fields may be combined to create a single combined density field that represents the entire design region 702. Any suitable technique may be used to create the combined density field, including but not limited to a simple addition of the values from the separate density fields. In some embodiments, the separate density fields may be combined during creation by projecting each signed distance field onto a common density field at block 914 such that the common density field accumulates values for each of the features to be included.

After combination of the density fields, a step of binarization may take place such that negative values may be set to a value of zero, and positive values may be set to a value of one, to indicate the presence or absence of a given material for the set of structural parameters 806. In some embodiments, some values within a threshold range of zero may be assigned a real value between zero and one to indicate a partial amount of the voxel to be filled with the given material. In some embodiments, instead of a hard threshold, the values of the density map may be passed through a sigmoid function to assign most values within the density map to zero or one, but to leave a differentiable transition region close to zero so that gradients can pass through the density map during optimization.

Within the simulated environment 606, each of the plurality of voxels is associated with a structural value to describe the structural parameters, a field value to describe the field response (e.g., the electric and magnetic fields in one or more orthogonal directions) to physical stimuli (e.g., one or more excitation sources), and a source value to describe the physical stimuli.

At block 920, a simulated environment 606 is configured to be representative of the set of structural parameters 806. Once the structural parameters 806 are determined, the simulated environment 606 is configured (e.g., the number of voxels, shape/arrangement of voxels, and specific values for the structural value, field value, and/or source value of the voxels are set based on the structural parameters 806).

In some embodiments the simulated environment includes a design region optically coupled between a first communication region and a plurality of second communication regions. In some embodiments, the first communication region may correspond to an input region or port (e.g., where an excitation source originates), while the second communication may correspond to a plurality of output regions or ports (e.g., when designing an optical demultiplexer that optically separates a plurality of distinct wavelength channels included in a multi-channel optical signal received at the input port and respectively guiding each of the distinct wavelength channels to a corresponding one of the plurality of output ports). However, in other embodiments, the first communication region may correspond to an output region or port, while the plurality of second communication regions corresponds to a plurality of input ports or region (e.g., when designing an optical multiplexer that optically combines a plurality of distinct wavelength signals received at respective ones of the plurality of input ports to form a multi-channel optical signal that is guided to the output port).

At block 922, each of a plurality of distinct wavelength channels are mapped to a respective one of the plurality of second communication regions. The distinct wavelength channels may be mapped to the second communication regions by virtue of the design specification. For example, a loss function may be chosen that associates a performance metric of the physical device with power transmission from the input port to individual output ports for mapped channels. In one embodiment, a first channel included in the plurality of distinct wavelength channels is mapped to a first output port, meaning that the performance metric of the physical device for the first channel is tied to the first output port. Similarly, other output ports may be mapped to the same or different channels included in the plurality of distinct wavelength channels such that each of the distinct wavelength channels is mapped to a respective one of the plurality of output ports (i.e., second communication regions) within the simulated environment 606. In one embodiment, the plurality of second communication regions includes four regions and the plurality of distinct wavelength channels includes four channels that are each mapped to a corresponding one of the four regions. In other embodiments, there may be a different number of the second communication regions (e.g., 8 regions) and a different number of channels (e.g., 8 channels) that are each mapped to a respective one of the second communication regions. In some embodiments, only a single input port and a single output port may be included, such as for waveguide bends or other devices intended to change a direction of an incoming signal to another direction.

Block 924 illustrates performing an operational simulation 802 of the physical device within the simulated environment 606 operating in response to one or more excitation sources to determine a performance loss value 820. More specifically, in some embodiments an electromagnetic simulation is performed in which a field response of the photonic integrated circuit is updated incrementally over a plurality of time steps to determine how the how the field response of the physical device changes due to the excitation source. The field values of the plurality of voxels are updated in response to the excitation source and based, at least in part, on the structural parameters 806 of the integrated photonic circuit. Additionally, each update operation at a particular time step may also be based, at least in part, on a previous (e.g., immediately prior) time step.

Consequently, the operational simulation 802 simulates an interaction between the photonic device (i.e., the photonic integrated circuit) and a physical stimuli (i.e., one or more excitation sources) to determine a simulated output of the photonic device (e.g., at one or more of the output ports or regions) in response to the physical stimuli. The interaction may correspond to any one of, or combination of a perturbation, retransmission, attenuation, dispersion, refraction, reflection, diffraction, absorption, scattering, amplification, or otherwise of the physical stimuli within electromagnetic domain due, at least in part, to the structural parameters 806 of the photonic device and underlying physics governing operation of the photonic device. Thus, the operational simulation 802 simulates how the field response of the simulated environment 606 changes due to the excitation source over a plurality of time steps (e.g., from an initial to final time step with a pre-determined step size).

In some embodiments, the simulated output may be utilized to determine one or more performance metrics of the physical device. For example, the excitation source may correspond to a selected one of a plurality of distinct wavelength channels that are each mapped to one of the plurality of output ports. The excitation source may originate at or be disposed proximate to the first communication region (i.e., input port) when performing the operational simulation 802. During the operational simulation 802, the field response at the output port mapped to the selected one of the plurality of distinct wavelength channels may then be utilized to determine a simulated power transmission of the photonic integrated circuit for the selected distinct wavelength channel. In other words, the operational simulation 802 may be utilized to determine the performance metric that includes determining a simulated power transmission of the excitation source from the first communication region, through the design region, and to a respective one of the plurality of second communication regions mapped to the selected one of the plurality of distinct wavelength channels. In some embodiments, the excitation source may cover the spectrum of all of the plurality of output ports (e.g., the excitation source spans at least the targeted frequency ranges for the bandpass regions for each of the plurality of distinct wavelength channels as well as the corresponding transition band regions, and at least portions of the corresponding stopband regions) to determine a performance metric (i.e., simulated power transmission) associated with each of the distinct wavelength channels for the photonic integrated circuit. In some embodiments, one or more frequencies that span the passband of a given one of the plurality of distinct wavelength channels is selected randomly to optimize the design (e.g., batch gradient descent while having a full width of each passband including ripple in the passband that meets the target specifications). In the same or other embodiments, each of the plurality of distinct wavelength channels has a common bandwidth with different center wavelengths. The performance metric may then be used to generate a performance loss value for the initial design 834. The performance loss value may correspond to a difference between the performance metric and a target performance metric of the physical device.

In some embodiments, the loss metric 822 may include terms in addition to the performance loss value in order to optimize different aspects of the initial design 834. For example, in some embodiments, a term for a fabrication loss value may be included in the loss metric 822. One advantage of the use of geometric shape primitives is the particular ease with which compliance fabrication constraints can be determined and included within the loss metric 822.

Returning to FIG. 9B, block 926 illustrates backpropagating the loss metric 822 via the loss function through the simulated environment 606 to determine an influence of changes in the structural parameters 806 on the loss metric (i.e., structural gradient). The loss metric is treated as an adjoint or virtual source and is backpropagated incrementally from a final time step to earlier time steps in a backwards simulation to determine the structural gradient of the physical device.

Block 928 illustrates backpropagating the loss metric 822 through the simulated environment 606 to determine a feature gradient 852 similarly to the determination of the structural gradient. As discussed above, the feature presence function 850 is typically of a form through which gradients will not naturally flow during this process. Accordingly, a different function may be used for the feature gradient 852 than was used for the feature presence function 850. FIG. 11B illustrates a non-limiting example embodiment of a feature gradient function 1104 according to various aspects of the present disclosure. While the feature presence function 1102 illustrated in FIG. 11A included a discontinuity with an undefined slope at the feature presence cutoff 1106 and a zero slope below the feature presence cutoff 1106, the feature gradient function 1104 is specified to have a defined slope within a dead zone 1108 around the feature presence cutoff 1106, and also a non-zero slope in the area below the dead zone 1108. One non-limiting example statement of such a feature presence function 1102 is as follows:

$$f ( x ) = DZS \times ReLU ( x ) \times ( 1 - sigmoid ( b \times ( x - c ) ) ) + {y}_{min} \times sigmoid ( b \times ( x - c ) ) + ( {y}_{max} - {y}_{min} ) / ( 1 - c ) \times ReLU ( x - c )$$

wherein DZS is a “dead zone slope” of the function within the dead zone 1108, and c is the location of the feature presence cutoff 1106. The value of yₘᵢₙ represents the y-value of the function at the point of cutoff, and the value of yₘₐₓ represents the y-value of the function at x=1, such that these two values define the slope of the function in the linear region. The value of b controls the width of the smooth transition region between the dead zone slope and the linear regions. Larger values of b make the transition between the dead zone 1108 and the linear regions sharper, and smaller values of b make the transition between the dead zone 1108 and the linear regions more gradual. In the illustrated embodiment, suitable values for these variables are c=0.3, yₘᵢₙ=3, yₘₐₓ=10, and DZS=0.5. In some embodiments, each of these variables may be adjusted or specified by the design specification. In some embodiments, each of these variables may be tuned as a hyperparameter as part of the optimization. One will note that although for values of x near c (i.e., within the dead zone 1108), the function does not precisely match the value of y in the feature presence function 850, but the feature gradient function 1104 does allow the feature gradient 852 to be computed.

Returning to FIG. 9B, block 930 shows revising the design of the physical device (e.g., generated a revised description) by updating the features using the signed distance fields, the structural gradient, and the feature gradient to adjust the loss metric. The backpropagation is first applied to the structural parameters, from the structural parameters to the density field, from the density field to the signed distance fields, and from the signed distance fields to the features of the initial design 834. By using differentiable functions to convert from geometric shape primitives to signed distance fields, the gradients can flow all the way back to the geometric shape primitives. In other words, the optimizer obtains

$$\frac{d L}{d \{ r , {x}_{c} , {y}_{c} \}}$$

via:

$$\frac{d L}{d \{ r , {x}_{c} , {y}_{c} \}} = \frac{d L}{dSDF} \cdot \frac{dSDF}{d \{ r , {x}_{c} , {y}_{c} \}} ,$$

with

$$\frac{dSDF}{d \{ r , {x}_{c} , {y}_{c} \}}$$

being obtainable from the analytic function defining the values for the signed distance field provided above. Similarly, the backpropagation may be applied concurrently (or sequentially) using the feature gradient 852 to the values that are provided as input to the feature presence function 850 to further adjust the loss metric.

In some embodiments, adjusting for the loss metric may reduce the loss metric. However, in other embodiments, the loss metric may be adjusted or otherwise compensated in a manner that does not necessarily reduce the loss metric. In some embodiments, the revised description is generated by utilizing an optimization scheme after a cycle of operational and adjoint simulations via a gradient descent algorithm, Markov Chain Monte Carlo algorithm, or other optimization techniques. Put in another way, iterative cycles of simulating the physical device, determining a loss metric, backpropagating the loss metric, updating the structural parameters to adjust the loss metric, and updating the geometric shape primitives using the signed distance fields may be successively and iteratively performed until the loss metric substantially converges such that the difference between the performance metric and the target performance metric is within a threshold range. In some embodiments, the term “converges” may simply indicate the difference is within the threshold range and/or below some threshold value.

At decision block 932, a determination is made regarding whether optimization of the design of the physical device is done. In some embodiments, optimization of the design of the physical device may be done when it is determined that the loss metric 822 has reached an acceptable value, such as a value specified by the design specification. In some embodiments, optimization of the design of the physical device may be done after a predetermined number of iterations.

If the determination is that optimization is not yet done, then the result of decision block 932 is NO, and the method 900 returns to block 912 to iterate on the updated features. Otherwise, if the determination is that optimization is done, then the result of decision block 932 is YES and the method 900 advances to block 934.

Block 934 illustrates outputting the updated design of the physical device. The updated design may be output to a computer-readable medium for storage and later operations, including but not limited to fabrication, further optimization, or inclusion in additional designs. In some embodiments, the updated design may be output to a fabrication system for fabrication of the physical device. In some embodiments, the updated design may be output to the fabrication system by providing a grid of voxels that each indicate a material to be included at a corresponding position of the physical device. In some embodiments, the updated design may be output to the fabrication system by outputting the list of geometric shape primitives itself, which may then be ingested by the fabrication system for fabricating the physical device.

The method 900 then proceeds to an end block and terminates.

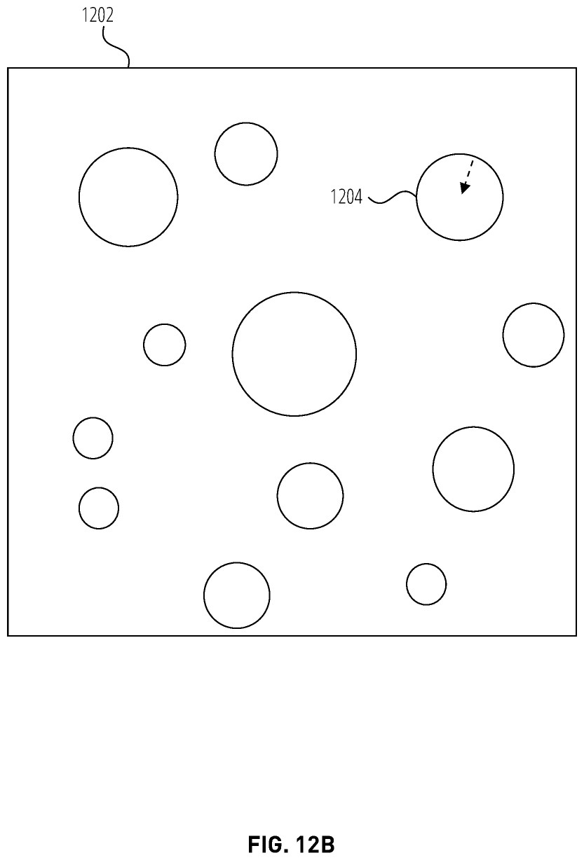

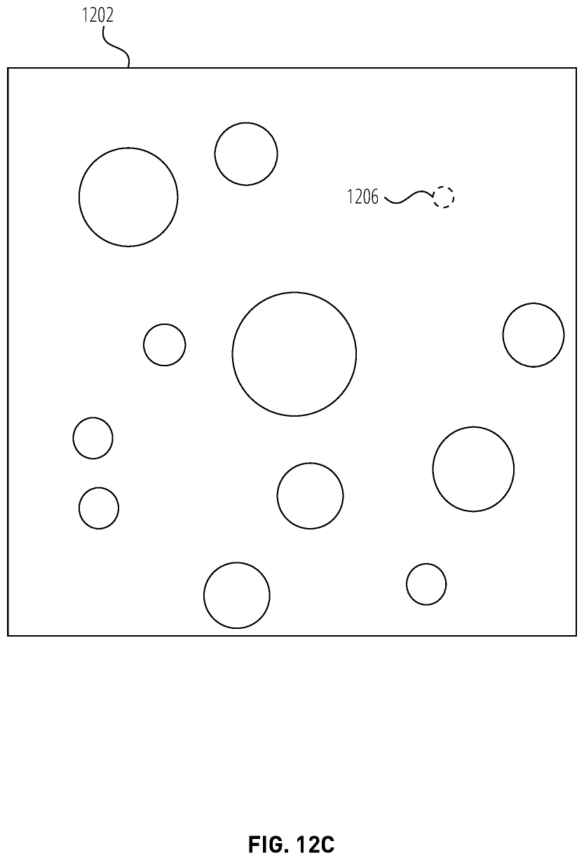

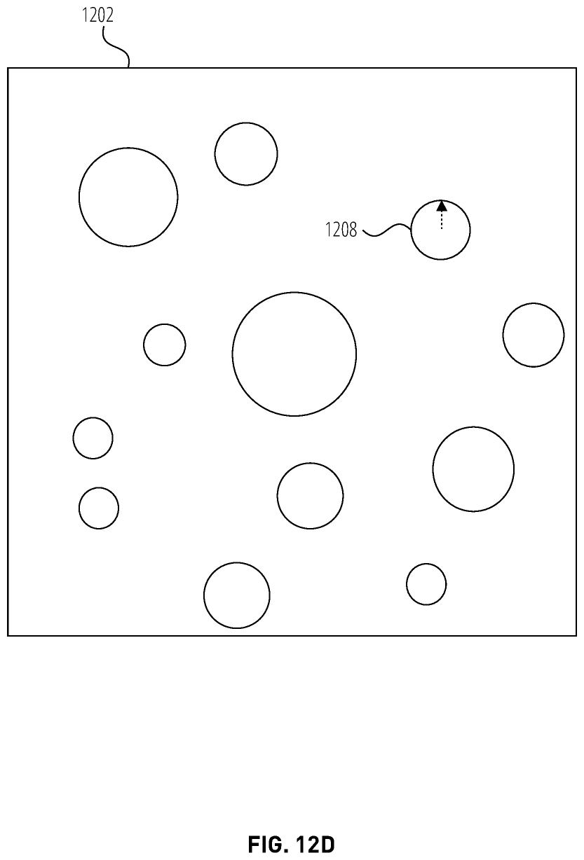

By using a differentiable function to generate the feature gradient 852, gradient optimization can be used to both add and remove features from the structural parameters 806. Since the slope of the feature gradient 852 within the dead zone 1108 is defined, and a non-zero slope is provided for values below the dead zone 1108, gradient optimization can allow values to move both ways past the value for the feature presence cutoff 1106 value during iterations of the optimization loop. FIG. 12A-FIG. 12D illustrate changes to a design that may be introduced by iterations of the optimization loop described above. In these Figures, a design region 1202 is illustrated that includes a plurality of features, including geometric shape primitive 1204. For the sake of simplicity, other features within the design region 1202 are not illustrated as changing during the optimization iterations in order to avoid obscuring the changes to geometric shape primitive 1204, but one will recognize that in an actual implementation of the optimization technique described above, each of the illustrated features may be changed similarly to the illustrated changes to geometric shape primitive 1204.

In FIG. 12A, the geometric shape primitive 1204 is illustrated at a beginning size and location. A dashed arrow indicates that, during a current iteration of the optimization loop, the structural gradient indicates that the geometric shape primitive 1204 should be smaller. The optimization process would then use the structural gradient to update the parameters defining the geometric shape primitive 1204 to reduce its size, and would also use the feature gradient to update the values used to determine the feature presence for the geometric shape primitive 1204. These values may be the same as the value used to determine the size of the geometric shape primitive 1204, or may be a separate value.

FIG. 12B illustrates the result of the update provided after FIG. 12A, in that the geometric shape primitive 1204 is illustrated as being smaller. The size of the geometric shape primitive 1204 remains above the feature presence cutoff 1106 value, and so the geometric shape primitive 1204 remains present within the structural parameters represented by the design region 1202. A dashed arrow in FIG. 12B indicates that, during this next iteration of the optimization loop, the structural gradient again indicates that the geometric shape primitive 1204 should be smaller still. The optimization process would then again use the structural gradient to update the parameters defining the geometric shape primitive 1204 to further reduce its size, and again use the feature gradient to update the values used to determine the feature presence.

FIG. 12C illustrates the result of the update provided after FIG. 12B. In FIG. 12C, the feature presence function 850 indicates that the geometric shape primitive should no longer be included in the structural parameters. Hence, the removed geometric shape primitive 1206 is illustrated in dashed line to indicate that it is not included in the structural parameters 806 to be simulated in the next simulation step. The feature presence function 850 may have determined this because a size of the removed geometric shape primitive 1206 has fallen below the feature presence cutoff 1106 threshold value. The next iteration of the optimization process would once again use the structural gradient to update the parameters defining the features, as well as the values used to determine the feature presence.

FIG. 12D illustrates the result of the update provided after FIG. 12C. In FIG. 12D, a dashed arrow indicates that the structural gradient and the feature gradient indicated that the returned geometric shape primitive 1208 should be included in the structural parameters, and that the size of the returned geometric shape primitive 1208 should be larger. Accordingly, FIG. 12D shows that the previously removed feature has been added back in by the optimization process.

In the preceding description, numerous specific details are set forth to provide a thorough understanding of various embodiments of the present disclosure. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

The order in which some or all of the blocks appear in each method flowchart should not be deemed limiting. Rather, one of ordinary skill in the art having the benefit of the present disclosure will understand that actions associated with some of the blocks may be executed in a variety of orders not illustrated, or even in parallel.

The processes explained above are described in terms of computer software and hardware. The techniques described may constitute machine-executable instructions embodied within a tangible or non-transitory machine (e.g., computer) readable storage medium, that when executed by a machine will cause the machine to perform the operations described. Additionally, the processes may be embodied within hardware, such as an application specific integrated circuit (“ASIC”) or otherwise.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific embodiments disclosed in the specification. Rather, the scope of the invention is to be determined entirely by the following claims, which are to be construed in accordance with established doctrines of claim interpretation.

What is claimed is:

1. A non-transitory computer-readable medium having logic stored thereon that, in response to execution by one or more processors of a computing system, causes the computing system to perform actions for designing a physical device, the actions comprising:
generating, by the computing system, an initial design based on a design specification, wherein the initial design includes a list of features;
for each feature of the list of features, determining whether the feature is present in a set of structural parameters by:
in response to determining a feature presence function indicates that the feature should be included in the set of structural parameters, updating the set of structural parameters to include the feature; and
in response to determining the feature presence function indicates that the feature should not be included in the set of structural parameters, refraining from updating the set of structural parameters to include the feature;
simulating, by the computing system, performance of the initial design using the set of structural parameters to determine a performance loss value;
determining, by the computing system, a structural gradient based on the performance loss value;
determining, by the computing system, a feature gradient based on the performance loss value; and
updating, by the computing system, the features in the list of features based on the structural gradient and the feature gradient.

2. The non-transitory computer-readable medium of claim 1, wherein the feature presence function has an undefined slope for at least one value, and wherein the feature gradient is based on a function that has a defined slope for the at least one value.

3. The non-transitory computer-readable medium of claim 2, wherein the feature presence function compares a size of the feature to a minimum feature size.

4. The non-transitory computer-readable medium of claim 3, wherein the features are circles defined by a location and a radius, and wherein comparing the size of the feature to the minimum feature size includes comparing the radius to the minimum feature size.

5. The non-transitory computer-readable medium of claim 1, wherein updating the set of structural parameters to include the feature comprises:
determining a signed distance field for the feature; and
projecting the signed distance field onto a density field.

6. The non-transitory computer-readable medium of claim 1, wherein the actions further comprise repeating the determining whether each feature is present, simulating, determining the structural gradient, determining the feature gradient, and updating steps for at least two iterations.

7. The non-transitory computer-readable medium of claim 6, wherein a first iteration includes refraining from updating the set of structural parameters to include a given feature, wherein a second iteration includes updating the set of structural parameters to include the given feature, and wherein the second iteration is after the first iteration.

8. The non-transitory computer-readable medium of claim 1, wherein the actions further comprise transmitting the list of features to a fabrication system for fabricating the physical device.

9. The non-transitory computer-readable medium of claim 8, wherein the fabrication system includes a photolithography system.

10. The non-transitory computer-readable medium of claim 1, wherein the physical device is an optoelectronic device.

11. A computer-implemented method for designing a physical device, the method comprising:
generating, by a computing system, an initial design based on a design specification, wherein the initial design includes a list of features;
for each feature of the list of features, determining whether the feature is present in a set of structural parameters by:
in response to determining a feature presence function indicates that the feature should be included in the set of structural parameters, updating the set of structural parameters to include the feature; and
in response to determining the feature presence function indicates that the feature should not be included in the set of structural parameters, refraining from updating the set of structural parameters to include the feature;
simulating, by the computing system, performance of the initial design using the set of structural parameters to determine a performance loss value;
determining, by the computing system, a structural gradient based on the performance loss value;
determining, by the computing system, a feature gradient based on the performance loss value; and
updating, by the computing system, the features in the list of features based on the structural gradient and the feature gradient.

12. The method of claim 11, wherein the feature presence function has an undefined slope for at least one value, and wherein the feature gradient is based on a function that has a defined slope for the at least one value.

13. The method of claim 12, wherein the feature presence function compares a size of the feature to a minimum feature size.

14. The method of claim 13, wherein the features are circles defined by a location and a radius, and wherein comparing the size of the feature to the minimum feature size includes comparing the radius to the minimum feature size.

15. The method of claim 11, wherein updating the set of structural parameters to include the feature comprises:
determining a signed distance field for the feature; and
projecting the signed distance field onto a density field.

16. The method of claim 11, further comprising repeating the determining whether each feature is present, simulating, determining the structural gradient, determining the feature gradient, and updating steps for at least two iterations.

17. The method of claim 16, wherein a first iteration includes refraining from updating the set of structural parameters to include a given feature, wherein a second iteration includes updating the set of structural parameters to include the given feature, and wherein the second iteration is after the first iteration.

18. The method of claim 11, further comprising transmitting the list of features to a fabrication system for fabricating the physical device.

19. The method of claim 18, wherein the fabrication system includes a photolithography system.

20. The method of claim 11, wherein the physical device is an optoelectronic device.
